(19) United States
(12) Patent Application Publication
(10) Pub. No.: US 2026/0365870 A1
(43) Pub. Date: Nov. 19, 2026

(54) COMPOSITION

(71) Applicant: Samsung Electronics Co., Ltd., Suwon-Si (KR)

(72) Inventors: Chang-Suk CHOI, Pyeongtaek (KR); Myoung-Gi JO, Pyeongtaek (KR); Sojeong AHN, Pyeongtaek (KR)

(21) Appl. No.: 19/120,323

(22) PCT Filed: Oct. 12, 2023
(86) PCT No.: PCT/EP2023/078271

§ 371 Date: Apr. 11, 2025

(30) Foreign Application Priority Data
Oct. 14, 2022 (EP) 22201591.9

(51) Int. Cl. C09D 11/50; B82Y 20/00; B82Y 40/00; C09D 11/101; C09D 11/107; C09K 11/02; C09K 11/08; C09K 11/88; H10H 20/851

(52) U.S. Cl. CPC C09D 11/50; C09D 11/101; C09D 11/107; C09K 11/02; C09K 11/0883; C09K 11/883; H10H 20/8512; B82Y 20/00; B82Y 40/00

(57) ABSTRACT

The present invention relates to a composition containing a light emitting moiety; and a process for fabricating the composition.

### FIELD OF THE INVENTION

The present invention relates to a composition containing a light emitting moiety; a process for preparing the composition; use of a composition, method for forming a layer; a layer; a color conversion device; and an optical device.

### BACKGROUND ART

WO 2021/116139 A1 discloses QD inks containing QDs, monomer mixtures (e.g. HDDMA and LA).

### PATENT LITERATURE

1. WO 2021/116139 A1

### NON-PATENT LITERATURE

No literature

### SUMMARY OF THE INVENTION

However, the inventors newly have found that there is still one or more of considerable problems for which improvement is desired, as listed below; no color change of a composition containing light emitting moiety under air condition, improved thermal stability of an obtained layer (film), improved thermal stability of a light emitting moiety in a layer (film), improved dispersibility of a light emitting moiety in a composition, enabling a phase separation of light emitting moiety and matrix material after curing realizing an improved haze value of the cured film (cured composition), improved dispersibility of a light emitting moiety in an obtained layer, improved long term Quantum Yield (QY) stability of a light emitting moiety in the composition in a longer term storage with our without external light irradiation, improved long term External Quantum Efficiency (EQE) stability of a light emitting moiety in the composition in a longer term storage with our without external light irradiation, improved long term Quantum Yield (QY) stability of a light emitting moiety in the obtained layer (film) in a longer term storage with our without light external irradiation, improved long term External Quantum Efficiency (EQE) stability of a light emitting moiety in the obtained layer (film) in a longer term storage with our without external light irradiation, improved good compatibility of light emitting moiety with a matrix material in a composition and/or an obtained layer (film), and/or realizing easy handling of a composition containing a light emitting moiety and a matrix material, making composition suitable for inkjet printing.

The inventors aimed to solve one or more of the above-mentioned problems.

The present inventors have surprisingly found that one or more of the above described technical problems can be solved by the features as defined in the claims.

Namely, it was found a novel composition, preferably it is being of a photocurable composition, comprising at least;
i) a light emitting moiety, preferably it is a semiconducting light emitting nanoparticle,
ii) at least one reactive monomer or a mixture of two or more reactive monomers, preferably said monomer having one or more of functional groups, more preferably it is a (meth)acrylate monomer; and
iii) a chemical compound represented by following chemical formula (X^{a}).

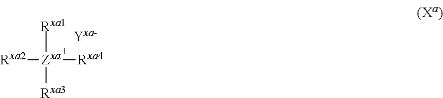

wherein
R^{xa1}, R^{xa1}, R^{xa1}, R^{xa1} are each independently of each other, selected from straight chain alkyl group having 1-25 carbon atoms, preferably 1 to 15 carbon atoms; a branched or cyclic alkyl group having 3-25 carbon atoms, preferably 3-15 carbon atoms; a straight-chain alkenyl or alkynyl group having 2 to 25 carbon atoms, preferably 2 to 15 carbon atoms; a branched alkenyl group or alkynyl group having 3 to 25 carbon atoms, preferably 3 to 15 carbon atoms; an aromatic or heteroaromatic ring system having 5 to 25 aromatic ring atoms, preferably 5 to 15 aromatic ring atoms; each of which may be substituted by one or more groups R^{a},
R^{a} is at each occurrence, identically or differently, H, D, a straight chain alkyl or alkoxy group having 1 to 40 carbon atoms, preferably 1 to 25 carbon atoms, more preferably 1 to 15 carbon atoms; a branched or cyclic alkyl or alkoxy group having 3 to 40 carbon atoms, preferably 3 to 25 carbon atoms, more preferably 3 to 15 carbon atoms; a straight-chain alkenyl or alkynyl group having 2 to 40 carbon atoms, preferably 2 to 24 carbon atoms, more preferably 2 to 12 carbon atoms; a branched alkenyl group or alkynyl group having 3 to 40 carbon atoms, preferably 3 to 24 carbon atoms, more preferably 3 to 12 carbon atoms; an aromatic or heteroaromatic ring system having 5 to 40 aromatic ring atoms, preferably 5 to 25 aromatic ring atoms, more preferably 5 to 18 aromatic ring atoms, wherein in each of the above-mentioned groups one or more H atoms may be replaced by D, F, Cl, Br, I, and where two or more adjacent substituents R^{a} here may optionally form a mono- or polycyclic, aliphatic ring system with one another;
Z^{xa} is N, P or As, preferably it is N or P, more preferably N;
Y^{xa-} is a halogen containing monovalent anion, preferably it is selected from the group consisting of F⁻, Cl⁻, Br⁻, I⁻, At⁻, Ts⁻, BF⁴⁻, PF⁶⁻, more preferably it is F⁻, Cl⁻, Br⁻, I⁻, BF⁴⁻, PF⁶⁻, even more preferably it is Br⁻, F⁻, Cl⁻ furthermore preferably it is Br⁻.

In another aspect, the present invention further relates to a process for preparing the composition of any one of preceding claims, comprising at least following steps,
(a) mixing a light emitting moiety, at least one reactive monomer or a mixture of two or more reactive monomers and a chemical compound represented by following chemical formula (Xa) to from a composition.

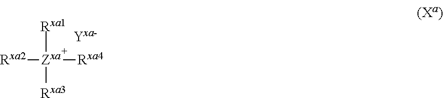

where symbols R^{xa1}, R^{xa1}, R^{xa1}, R^{xa1}, Z^{xa}, Y^{xa-} are as defined in the specification.

Optionally, a thiol containing chemical compound and/or a chemical compound as defined in the specification, is (are) added in step (a).

In another aspect, the present invention relates to a composition obtainable or obtained from the process of the present invention.

In another aspect, the present invention relates to use of the composition, in an electronic device, optical device, sensing device or a biomedical device.

In another aspect, the present invention relates to a method for forming a layer comprising:
S1) providing the composition of the present invention onto a substrate, preferably by ink-jetting,
S2) curing the composition, preferably said curing is a photo curing performed by photo irradiation, thermal curing or a combination of a photo curing and a thermal curing.

In another aspect, the present invention further relates to a layer obtained or obtainable from the method of the present invention.

In another aspect, the present invention further relates to a layer containing at least, mainly consisting of or consisting of;
Xi) a light emitting moiety, preferably it is a semiconducting light emitting nanoparticle;
Xii) a polymer made from at least one reactive monomer or a mixture of two or more reactive monomers, preferably said monomer having one or more of functional groups, more preferably it is a(meth)acrylate monomer;
Xiii) a chemical compound represented by following chemical formula (Xa)

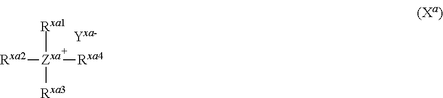

where symbols R^{xa1}, R^{xa1}, R^{xa1}, R^{xa1} Z^{xa}, Y^{xa-} are as defined in the specification.

In another aspect, the present invention further relates to a color conversion device (100) comprising at least a 1^{st} pixel (161) partly or fully filled with the layer of the present invention comprising at least a matrix material (120) containing a light emitting moiety (110), and a bank (150) comprising at least a polymer material, preferably the color conversion device (100) further contains a supporting medium (170).

In another aspect, the present invention further relates to an optical device (300) containing at least one functional medium (320, 420, 520) configured to modulate a light or configured to emit light, and the layer of the present invention or 22 or the color conversion device (100) of the present invention.

### DESCRIPTION OF DRAWINGS

FIG. 1: shows a cross sectional view of a schematic of one embodiment of a color conversion film (100).

FIG. 2: shows a top view of a schematic of another embodiment of a color conversion film (100) of the invention.

FIG. 3: shows a cross sectional view of a schematic of one embodiment of an optical device (300) of the invention.

FIG. 4: shows a cross sectional view of a schematic of another embodiment of an optical device (300) of the invention.

FIG. 5: shows a cross sectional view of a schematic of another embodiment of an optical device (300) of the invention.

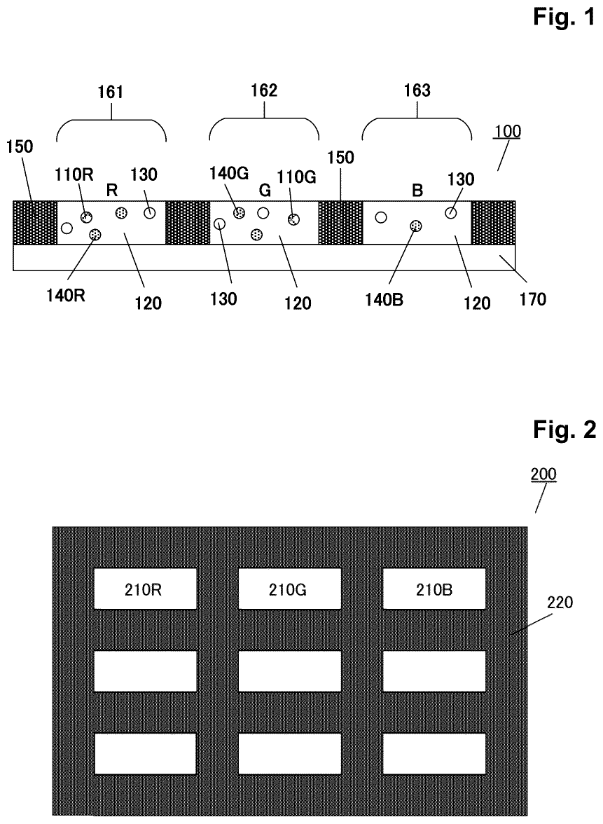

### LIST OF REFERENCE SIGNS IN FIG. 1

100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
161. a 1^{st} pixel
162. a 2^{nd} pixel
163. a 3^{rd} pixel
170. a supporting medium (a substrate) (optional)

### LIST OF REFERENCE SIGNS IN FIG. 2

200. a color conversion film
210R. a pixel (red)
210G. a pixel (green)
210B. a pixel (blue)
220. a bank

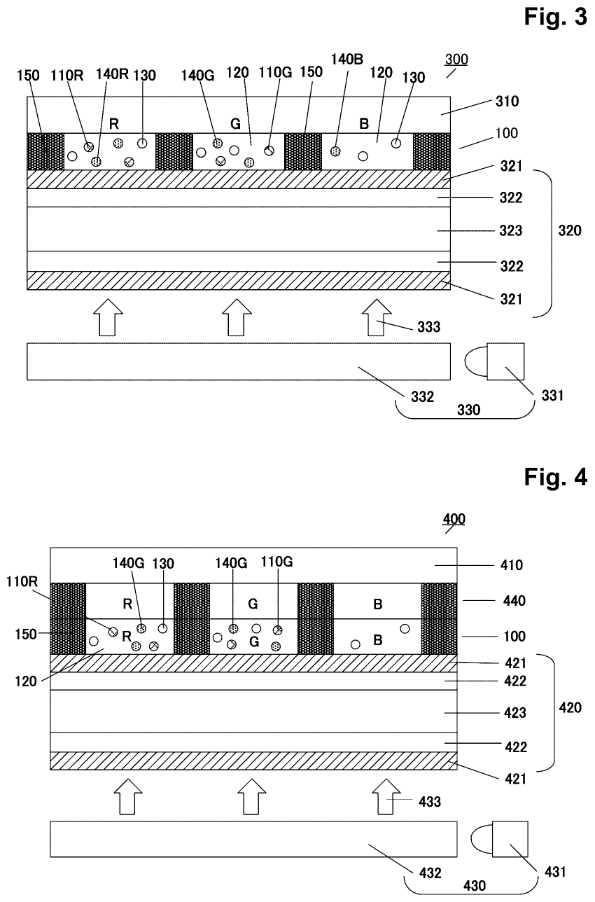

### LIST OF REFERENCE SIGNS IN FIG. 3

300. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
310. a substrate
320. a light modulator
321. a polarizer
322. an electrode
323. a liquid crystal layer
330. a light source
331. a LED light source
332. a light guiding plate (optional)
333. light emission from the light source (330)

### LIST OF REFERENCE SIGNS IN FIG. 4

400. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
410. a substrate
420. a light modulator
421. a polarizer
422. an electrode
423. a liquid crystal layer
430. a light source
431. a LED light source
432. a light guiding plate (optional)
440. a color filter
433. light emission from the light source (330)

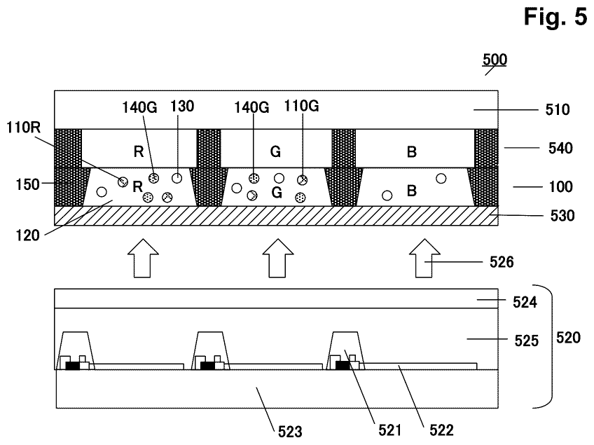

### LIST OF REFERENCE SIGNS IN FIG. 5

500. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
510. a substrate
520. a light emitting device (e.g., OLED)
521. a TFT
522. an electrode (anode)
523. a substrate
524. an electrode (cathode)
525. light emitting layer (e.g., OLED layer(s))
526. light emission from a light emitting device (520)
530. an optical layer (e.g., polarizer) (optional)
540. a color filter

### DETAILED DESCRIPTION OF THE INVENTION

According to the present invention, a composition, preferably it is being of a photocurable composition, comprises at least, essentially consisting of or consisting of;
i) a light emitting moiety, preferably it is a semiconducting light emitting nanoparticle,
ii) at least one reactive monomer or a mixture of two or more reactive monomers, preferably said monomer having one or more of functional groups, more preferably it is a (meth)acrylate monomer; and
iii) a chemical compound represented by following chemical formula (X^{a}).

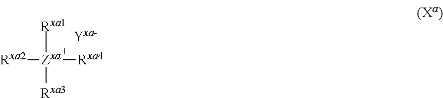

wherein
R^{xa1}, R^{xa1}, R^{xa1}, R^{xa1} are each independently of each other, selected from straight chain alkyl group having 1-25 carbon atoms, preferably 1 to 15 carbon atoms; a branched or cyclic alkyl group having 3-25 carbon atoms, preferably 3-15 carbon atoms; a straight-chain alkenyl or alkynyl group having 2 to 25 carbon atoms, preferably 2 to 15 carbon atoms; a branched alkenyl group or alkynyl group having 3 to 25 carbon atoms, preferably 3 to 15 carbon atoms; an aromatic or heteroaromatic ring system having 5 to 25 aromatic ring atoms, preferably 5 to 15 aromatic ring atoms; each of which may be substituted by one or more groups R^{a},
R^{a} is at each occurrence, identically or differently, H, D, a straight chain alkyl or alkoxy group having 1 to 40 carbon atoms, preferably 1 to 25 carbon atoms, more preferably 1 to 15 carbon atoms; a branched or cyclic alkyl or alkoxy group having 3 to 40 carbon atoms, preferably 3 to 25 carbon atoms, more preferably 3 to 15 carbon atoms; a straight-chain alkenyl or alkynyl group having 2 to 40 carbon atoms, preferably 2 to 24 carbon atoms, more preferably 2 to 12 carbon atoms; a branched alkenyl group or alkynyl group having 3 to 40 carbon atoms, preferably 3 to 24 carbon atoms, more preferably 3 to 12 carbon atoms; an aromatic or heteroaromatic ring system having 5 to 40 aromatic ring atoms, preferably 5 to 25 aromatic ring atoms, more preferably 5 to 18 aromatic ring atoms, wherein in each of the above-mentioned groups one or more H atoms may be replaced by D, F, Cl, Br, I, and where two or more adjacent substituents R^{a} here may optionally form a mono- or polycyclic, aliphatic ring system with one another;
Z^{xa} is N, P or As, preferably it is N or P, more preferably N;
Y^{xa-} is a halogen containing monovalent anion, preferably it is selected from the group consisting of F⁻, Cl⁻, Br⁻, I⁻, At⁻, Ts⁻, BF⁴⁻, PF⁶⁻, more preferably it is F⁻, Cl⁻, Br⁻, I⁻, BF⁴⁻, PF⁶⁻, even more preferably it is Br⁻, F⁻, Cl⁻ furthermore preferably it is Br.

### The Chemical Compound of Formula (X^{a})

According to the present invention, the composition comprises the chemical compound represented by following chemical formula (X^{a}) as indicated above. As the chemical compound of formula (X^{a}), publicly available chemical compound (halogen containing quaternary salt) can be used.

It is believed that the chemical compound of formula (X^{a}) reduces/prevents color change of the composition, and/or reduces/prevents sedimentation of light emitting moiety.

In a preferable embodiment of the present invention, from the view point of reducing/preventing color change of the composition and/or reducing/preventing sedimentation of light emitting moiety, R^{xa1}, R^{xa1}, R^{xa1}, R^{xa1} of the chemical formula (X^{a}) are each independently of each other, selected from straight chain alkyl group having 1-25 carbon atoms, preferably 1 to 15 carbon atoms; a branched or cyclic alkyl group having 3-25 carbon atoms, preferably 3-15 carbon atoms; a straight-chain alkenyl or alkynyl group having 2 to 25 carbon atoms, preferably 2 to 15 carbon atoms; a branched alkenyl group or alkynyl group having 3 to 25 carbon atoms, preferably 3 to 15 carbon atoms; each of which may be substituted by one or more groups R^{a}, more preferably R^{xa1}, R^{xa1}, R^{xa1}, R^{xa1} are each independently of each other, selected from straight chain alkyl group having 1-25 carbon atoms, preferably 1 to 15 carbon atoms; a branched alkyl group having 3-25 carbon atoms, preferably 3-15 carbon atoms; each of which may be substituted by one or more groups R^{a}.
Z^{xa} is N, P or As, preferably it is N or P, more preferably N;
Y^{xa-} is a halogen containing monovalent anion, preferably it is selected from the group consisting of F⁻, Cl⁻, Br⁻, I⁻, At⁻, Ts⁻, BF⁴⁻, PF⁶⁻, more preferably it is F⁻, Cl⁻, Br⁻, I⁻, BF⁴⁻, PF⁶⁻, even more preferably it is Br⁻, F⁻, Cl⁻ furthermore preferably it is Br⁻.

Further, rom the view point of reducing/preventing color change of the composition and/or reducing/preventing sedimentation of light emitting moiety, preferably, the total amount of the chemical compound of chemical formula (X^{a}) is in the range from 0.001 to 2.0 wt % based on the total amount of the composition without solvent, preferably it is in the range from 0.01 to 1.9 wt %, more preferably from 0.02 to 1.8 wt %, even more preferably 0.03 to 1.6 wt %, furthermore preferably 0.04 to 1.4 wt %.

According to the present invention, said chemical compound of chemical formula (X^{a}) can be just added to the composition as an additive, it can be introduced onto the surface of the light emitting moiety (e.g. QD) as a ligand material by publicly known ligand exchange process.

As the chemical compound of chemical formula (X^{a}), any publicly known halide containing quaternary salt material falls under the definition of chemical formula (X^{a}) can be used.

For examples, ammonium bromides, ammonium fluorides, ammonium chlorides, ammonium iodides, other ammonium salts having halide ion, like disclosed in the brochure on quaternary ammonium salts of TCI numbered Q6003E 20191018, available for example on www.TCIchemicals.com, such as hexamethonium bromide, dimethyldioctylammonium bromide, tetrabutylammonium bromide, trimethylpropylmmonium bromide, n-octyltrimethylammonium bromide, tetramethylammonium bromide, dilauryldimethylammonium bromide, heptadecyltrimethylammonium bromide, butyltrimethylammonium bromide, trimethylstearylammonium bromide, decamethonium bromide, Ethylhexadecyldimethylammonium bromide, didodecyldimethylammonium bromide, Hexadecyltrimethylammonium bormide (CTAB), Tetrabutylammonium bromide (TBAB), tetrabutylammonium iodide, tetrapropylammonium iodide, tetrabutylammonium fluoride, tetrapropylammonium chloride, tetrabutylammonium perchlorate, tetrabutylammonium hexafluorophosphate, tetrabutylammonium tetrafluoroborate, can be used. Among then, hexamethonium bromides are more preferable. Furthermore preferably, didodecyldimethylammonium bromide, Hexadecyltrimethylammonium bormide (CTAB), Tetrabutylammonium bromide (TBAB) can be used to prevent the color change of the composition cased in Air condition.

### Thiol Containing Chemical Compound

In a preferable embodiment of the present invention, the composition further comprises a thiol containing chemical compound. Preferably the total amount of the thiol containing chemical compound is in the range from 0.1 to 20 wt % based on the total amount of the composition without solvent, more preferably it is 1 to 15 wt %, even more preferably it is 5 to 10 wt %. Preferably it is represented by following chemical formula (P^{XA}).

R^{xa1}—SH (P^{XA})
wherein
R^{xa1} is selected from a straight chain alkyl group having 1-40 carbon atoms, preferably 5 to 30 carbon atoms; a branched or cyclic alkyl group having 3-40 carbon atoms, preferably 5-30 carbon atoms; a straight-chain alkenyl or alkynyl group having 2 to 40 carbon atoms, preferably 5 to 30 carbon atoms; a branched alkenyl group or alkynyl group having 3 to 40 carbon atoms, preferably 5 to 30 carbon atoms; an aromatic or heteroaromatic ring system having 5 to 40 aromatic ring atoms, preferably 5 to 30 aromatic ring atoms; each of which may be substituted by one or more groups R^{a},
R^{a} is at each occurrence, identically or differently, H, D, a straight chain alkyl or alkoxy group having 1 to 40 carbon atoms, preferably 1 to 25 carbon atoms, more preferably 1 to 15 carbon atoms; a branched or cyclic alkyl or alkoxy group having 3 to 40 carbon atoms, preferably 3 to 25 carbon atoms, more preferably 3 to 15 carbon atoms; a straight-chain alkenyl or alkynyl group having 2 to 40 carbon atoms, preferably 2 to 24 carbon atoms, more preferably 2 to 12 carbon atoms; a branched alkenyl group or alkynyl group having 3 to 40 carbon atoms, preferably 3 to 24 carbon atoms, more preferably 3 to 12 carbon atoms; an aromatic or heteroaromatic ring system having 5 to 40 aromatic ring atoms, preferably 5 to 25 aromatic ring atoms, more preferably 5 to 18 aromatic ring atoms, wherein in each of the above-mentioned groups one or more H atoms may be replaced by D, F, Cl, Br, I, and where two or more adjacent substituents R^{a} here may optionally form a mono- or polycyclic, aliphatic ring system with one another. Said thiol containing chemical compound can be just added to the composition as a ligand additive, it can be introduced onto the surface of the light emitting moiety (e.g. QD) as a ligand material by publicly known ligand exchange process or it can be introduced onto the surface of the light emitting moiety by crystal bounding like described in WO2020/216813 A1.

Preferably, the sum of the total amount of chemical compound of chemical formula (X^{a}) of claim 3 and the total amount of the thiol containing chemical compound of claim 4 is in the range from 0.1 to 20 wt % based on the total amount of the composition without solvent, more preferably it is 1 to 15 wt %, even more preferably it is 5 to 10 wt %.

As the thiol containing chemical compound, publicly known thiol containing chemical compound which fits to the definition of the thiol containing chemical compound of the present invention can be used.

For examples,
HS—(CH₂)₇—CH₃
HS—(CH₂)₁₁—CH₃
HS—(CH₂)₁₇—CH₃
1-octadecanethiol
Dodecanethiol
   mPEG Thiol Like Chemical Compound

In a preferable embodiment of the present invention, the composition further comprises a chemical compound comprising at least one group selected from the group consisting of straight-chain alkyl group having carbon atoms 1 to 80 or branched-chain alkyl group having carbon atoms 3 to 80, straight-chain aryl-alkyl group having carbon atoms 5 to 45, branched-chain aryl-alkyl group having carbon atoms 6 to 45, straight-chain cyclo-alkyl group having carbon atoms 4 to 45; and branched-chain cyclo-alkyl group having carbon atoms 6 to 45, where one or more non-adjacent CH₂ groups of the above mentioned groups is replaced by oxygen atom, C═O, C═S, C═Se, C═NH, SiH₂, SO, SO₂, OS, or CONH and where one or more H atoms may be replaced by D, F, Cl, Br, I, CN or NO₂; preferably the molecular weight of said chemical compound is 2000 or less, more preferably 1000 or less, even more preferably 500 or less and the molecular weight of said chemical compound is preferably 100 or more, more preferably 200 or more, even more preferably 300 or more, preferably said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid.

Said chemical compound can be just added to the composition as a ligand additive, it can be introduced onto the surface of the light emitting moiety (e.g. QD) as a ligand material by publicly known ligand exchange process or it can be introduced onto the surface of the light emitting moiety by crystal bounding like described in WO2020/216813 A1.

For examples, the chemical compound can be described as follows preferably.
HS—CH₂—(OCH₂CH₂)₄—O—CH₃
HS—CH₂—(OCH₂CH₂)₆—O—CH₃
HS—CH₂—(OCH₂CH₂)₈—O—CH₃
HS—(CH₂)₂—(OCH₂CH₂)₂—O—CH₃
HS—(CH₂)₂—(OCH₂CH₂)₆—O—CH₃
HS—(CH₂)₂—(OCH₂CH₂)₈—O—CH₃
HS—(CH₂)₂—(OCH₂CH₂)₁₆—O—CH₃
HS—(CH₂)₂—(OCH₂CH₂)₁₇—O—CH₃
HS—(CH₂)₂—(OCH₂CH₂)₆—CH₃
HS—(CH₂)₂—(OCH₂CH₂)₆—O—(CH₂)₂—SH
HS—(CH₂)₇—CH₃
HSe—(CH₂)₇—CH₃
HS—(CH₂)₁₁—CH₃
HSe—(CH₂)₁₁—CH₃
HS—(CH₂)₁₇—CH₃
HSe—(CH₂)₁₇—CH₃

Other thiolated ligand materials like polypropyleneglycol and polypropyleneglycol monomethyl ether, thiolated ligand materials described in U.S. Ser. No. 11/021,651 B2, formula (I), formula (II) of column 17-18, line 28 of column 25 to line 16 of column 26, M1000-SH of Example 1 can also be used. It case of crystal bounding like described in WO2020/216813 A1 is performed, above mentioned materials are used as a source of organic moiety and the resulting covalently bonded organic moiety is included as the chemical compound in this patent application.

It is believed that the chemical compound prevents aggregation of nanoparticles or nanosized material, the organic moiety allows to disperse the nanoparticles in the organic medium and/or in aqueous medium.

### Light Emitting Moiety

According to the present invention, said light emitting moiety may be an organic and/or inorganic light emitting material, preferably it is an organic dye, inorganic phosphor and/or a semiconducting light emitting nanoparticle such as a quantum material. As said organic dye, inorganic phosphor, a semiconducting light emitting nanoparticle, a publicly known one can be used.

Such suitable inorganic light emitting materials described above can be well known phosphors including nanosized phosphors, quantum sized materials like mentioned in the phosphor handbook, 2^{nd} edition (CRC Press, 2006), pp. 155-pp. 338 (W. M. Yen, S. Shionoya and H. Yamamoto), WO2011/147517A, WO2012/034625A, and WO2010/095140A.

As organic dyes, for examples rhodamine, coumarin, pyrromethene, DCM, Fluorescein, umbelliferone, BD Horizon Brilliant™ series can be used.

Preferably said light emitting moiety is an inorganic light emitting material. More preferably it is a semiconducting light emitting nanoparticle. Said semiconducting light emitting nanoparticle is preferably a semiconducting light emitting nanoparticle, comprising, essentially consisting of, or consisting of, a core; optionally one or more of shell layers, and optionally an outer layer covering at least a part of said core, comprising a metal cation and a divalent anion; and
an organic moiety, preferably one or more types of organic moieties directly attached to the anion of the outer layer by covalent bond,
wherein said divalent anion is selected from Se²⁻, S²⁻, Te²⁻ O²⁻ or a combination of any of these, preferably said metal cation is a monovalent, divalent cation, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺. Or in some embodiments, metal cation is a transition metal of group 12 or group 14, preferably it is selected from one or more members of the group consisting of Zn²⁺, Hg²⁺ or Pb²⁺.

The outer layer covers at least a part of said core. The outer layer may have a direct physical contact with said core if there is no other layers between the outer layer and the core.

The outer layer may cover the core via one or more of additional layers placed between the outer layer and the core.

The term “cover” and the term “covering” do not necessarily mean that there is always a physical contact between the said core and the outer layer. Preferably the core is fully covered by an outer layer and/or one or more of shell layers.

Most preferably, said nanoparticle comprises a core, one or more of shell layers and one outer layer, wherein the outermost shell layer of said one or more of shell layers comprises Zn and S atom.

In a preferred embodiment of the present invention, said outer layer of the light emitting moiety comprises at least two or three different metal cations such as the combination of Cu¹⁺ and In³⁺, Cu¹⁺ and Ga³⁺, Ag¹⁺ and Ga³⁺ or a combination of Cu⁺¹/In⁺³/Zn⁺² from the view point of making an improved covalent bond between the organic moieties and the anions of the outer layer.

According to the present invention, the term “nanosized” means the size in between 0.1 nm and 150 nm, preferably 0.5 nm to 100 nm, more preferably 1 nm to 50 nm.

According to the present invention, the term “semiconductor” means a material having electrical conductivity to a degree between that of a conductor (such as copper) and that of an insulator (such as glass) at room temperature, preferably, a semiconductor is a material whose electrical conductivity increases with the temperature.

Therefore, according to the present invention, the term “semiconductor nanoparticle” is taken to mean that a material having electrical conductivity to a degree between that of a conductor (such as copper) and that of an insulator (such as glass) at room temperature, preferably, a semiconductor is a material whose electrical conductivity increases with the temperature and the size is in between 0.1 nm and 999 nm, preferably 0.5 nm to 150 nm, more preferably 1 nm to 50 nm.

According to the present invention, the term “size” means the average diameter of the circle with the area equivalent to the measured TEM projection of the semiconducting nanosized light emitting particles.

In a preferred embodiment of the present invention, the semiconducting light emitting nanoparticle of the present invention is a quantum sized material.

According to the present invention, the term “quantum sized” means the size of the first semiconducting nanoparticle itself without ligands or another surface modification, which can show the quantum confinement effect, like described in, for example, ISBN:978-3-662-44822-9.

Generally, it is said that the quantum sized materials can emit tunable, sharp and vivid colored light due to “quantum confinement” effect.

In some embodiments of the invention, the size of the overall structures of the quantum sized material, is from 1 nm to 50 nm.

In a preferred embodiment of the present invention, the average diameter of the first semiconducting nanoparticle (core) is in the range from 1 to 20 nm, preferably it is in the range from 1.5 to 12 nm.

The average diameter of the semiconducting light emitting nanoparticles (cores) are calculated based on 100 semiconducting light emitting nanoparticles in a TEM image taken by a Tecnai G2 Spirit Twin T-12 Transmission Electron Microscope. The average diameter of the semiconducting light emitting nanoparticles are calculated using Fiji_lmageJ program.

According to the present invention, said semiconducting light emitting nanoparticle may have a core-shell structure. In case said semiconducting light emitting nanoparticle does not have any shell layer, then the term “core” means semiconducting light emitting nanoparticle itself.

In some embodiments of the present invention, the core comprises at least one element of group 12 or group 13 elements of the periodic table and one element of group 15 or 16 elements of the periodic table.

In a preferred embodiment of the present invention, the 1^{st} semiconducting material (hereafter “core” of the semiconducting light emitting nanoparticle”) comprises at least one element of the group 13 of the periodic table, and one element of the group 15 of the periodic table, preferably the element of the group 13 is In, and the element of the group 15 is P.

In a preferred embodiment of the present invention, the first core can further comprise additional element selected from one or more member of the group consisting of Ga, Zn, S, and Se.

In some embodiments the core is a metal oxide comprising for example ZnO, FeO, Fe₂O₃, ZrO₂, CuO, SnO Cu₂O, TiO₂, WO₃, HfO₂, In₂O₃, MgO, Al₂O₃ and any combination of these.

In some embodiments the core comprises a metal, for example Au, Ag, W, Pd, Pt, Cu, In, Ti, Zn, Pb, Al, Cd, Zn and a combination of any of these.

In a more preferable embodiment, the core is selected from the group consisting of InP, InPZn, InPZnS, InPZnSe, InPZnSeS, InPZnGa, InPGaS, InPGaSe, InPGaSeS, InPZnGaSeS and InPGa.

According to the present invention, a type of shape of the core of the semiconducting light emitting nanoparticle, and shape of the semiconducting light emitting nanoparticle to be synthesized are not particularly limited.

For examples, spherical shaped, elongated shaped, star shaped, polyhedron shaped, pyramidal shaped, tetrapod shaped, tetrahedron shaped, platelet shaped, cone shaped, and irregular shaped core and—or a semiconducting light emitting nanoparticle can be synthesized.

### Shell Layer

According to the present invention, in a preferable embodiment, the core is at least partially embedded in the first shell layer, more preferably said core is fully embedded into one or more shell layers. In a preferred embodiment of the present invention, said shell layer(s) are placed in between the core and the outer layer. In other words, the semiconducting light emitting nanoparticle of the present invention optionally may comprise, essentially consisting of, or consisting of a core, one or more shell layers covering said core, an outer layer covering said shell layers in this sequence.

### First Shell Layer

In some embodiments of the present invention, said shell layer comprises at least one metal cation and at least one divalent anion as described in the section of outer layer and/or at least a 1^{st} element of group 12 of the periodic table and a Se atom or a S atom, preferably, the 1^{st} element is Zn.

For example, said first shell layer is selected from the group consisting of Cs₂S, Cs₂Se, Cs₂Te, Cs₂O, Ag₂S, Ag₂Se, Ag₂Te, Ag₂O, Au₂S, Au₂Se, Au₂Te, Au₂O, Cu₂S, Cu₂Se, Cu₂Te, Cu₂O, ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe, In₂S₃, In₂Se₃, In₂Te₃, In₂O₃, Ga₂S₃, Ga₂Se₃, Ga₂Te₃, Ga₂O₃, Bi₂S₃, Bi₂Se₃, Bi₂Te₃, Bi₂O₃, Fe₂S₃, Fe₂Se₃, Fe₂Te₃, Fe₂O₃, TiS₂, TiSe₂, TiTe₂, TiO₂, SiS₂, SiSe₂, SiTe₂, SiO₂, ZrS₂, ZrSe₂, ZrTe₂, ZrO₂, HfS₂, HfSe₂, HfTe₂, HfO₂, SnS₂, SnSe₂, SnTe₂, SnO₂, GeS₂, GeSe₂, GeTe₂, GeO, CuInZnS, CuInS₂, CuInZnSe, CuInSe₂, AgInZnS, AgInZnSe, CuGaZnS, CuGaZnSe, CuFeS₂, CuFeSe₂ and a combination of any of these.

Preferably it is selected from the group consisting of ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe and a combination of any of these materials

More preferably: ZnS, ZnSe, ZnTe, ZnO or a combination of any of these materials

In some embodiments of the present invention, at least one (first) the shell layer comprises or a consisting of a 1^{st} element of group 12 of the periodic table and a 2^{nd} element of group 16 of the periodic table, preferably, the 1^{st} element is Zn, and the 2^{nd} element is S, Se, or Te; preferably a first shell layer covering directly onto said core comprises or a consisting of a 1^{st} element of group 12 of the periodic table and a 2^{nd} element of group 16 of the periodic table, preferably, the 1^{st} element is Zn, and the 2^{nd} element is S, Se, or Te.

In a preferred embodiment of the present invention, at least one shell layer (a first shell layer) is represented by following formula (XI), preferably the shell layer directly covering the core is represented by the chemical formula (XI);

ZnSₓSe_{y}Te_{z} (XI)

wherein 0≤x≤1, 0≤y≤1, 0≤z≤1, and x+y+z=1, preferably 0≤x≤1, 0≤y≤1, z=0, and x+y=1, preferably, the shell layer is ZnSe, ZnSₓSe_{y}, ZnS, ZnSe_{y}Te_{z} or ZnSₓTe_{z}.

In some embodiments of the present invention, said shell layer is an alloyed shell layer or a graded shell layer, preferably said graded shell layer is ZnSₓSe_{y}, ZnSe_{y}Te_{z}, or ZnSₓTe_{z}, more preferably it is ZnSₓSe_{y}.

In some embodiments of the present invention, the semiconducting light emitting nanoparticle further comprises 2^{nd} shell layer onto said shell layer, preferably the 2^{nd} shell layer comprises or a consisting of a 3^{rd} element of group 12 of the periodic table and a 4^{th} element of group 16 of the periodic table, more preferably the 3^{rd} element is Zn, and the 4^{th} element is S, Se, or Te with the proviso that the 4^{th} element and the 2^{nd} element are not same.

In some embodiments of the present invention, optionally, the first semiconducting nanoparticle as a core and a first shell layer can be at least partially embedded in the 2^{nd} shell, preferably said first semiconducting nanoparticle is fully embedded into the shell layer.

For example, said second shell layer is selected from the group consisting of Cs₂S, Cs₂Se, Cs₂Te, Cs₂O, Ag₂S, Ag₂Se, Ag₂Te, Ag₂O, Au₂S, Au₂Se, Au₂Te, Au₂O, Cu₂S, Cu₂Se, Cu₂Te, Cu₂O, ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe, In₂S₃, In₂Se₃, In₂Te₃, In₂₀₃, Ga₂S₃, Ga₂Se₃, Ga₂Te₃, Ga₂O₃, Bi₂S₃, Bi₂Se₃, Bi₂Te₃, Bi₂₀₃, Fe₂S₃, Fe₂Se₃, Fe₂Te₃, Fe₂O₃, TiS₂, TiSe₂, TiTe₂, TiO₂, SiS₂, SiSe₂, SiTe₂, SiO₂, ZrS₂, ZrSe₂, ZrTe₂, ZrO₂, HfS₂, HfSe₂, HfTe₂, HfO₂, SnS₂, SnSe₂, SnTe₂, SnO₂, GeS₂, GeSe₂, GeTe₂, GeO, CuInZnS, CuInS₂, CuInZnSe, CuInSe₂, AgInZnS, AgInZnSe, CuGaZnS, CuGaZnSe, CuFeS₂, CuFeSe₂ and a combination of any of these.

Preferably it is selected from the group consisting of ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe and a combination of any of these materials

More preferably: ZnS, ZnSe, ZnTe, ZnO or a combination of any of these materials.

In some embodiments of the present invention, said 2^{nd} shell layer comprises at least a 1^{st} element of group 12 of the periodic table and a 2^{nd} element of group 16 of the periodic table, preferably, the 1^{st} element is Zn, and the 2^{nd} element is S, Se, O, or Te.

In a preferred embodiment of the present invention, the 2^{nd} shell layer is represented by following formula (XI′),

ZnSₓSe_{y}Te_{z} (XI′)
wherein 0≤x≤1, 0≤y≤1, 0≤z≤1, and x+y+z=1, preferably, the shell layer is ZnSe, ZnSₓSe_{y}, ZnSe_{y}Te_{z}, or ZnSₓTe_{z} with the proviso that the shell layer and the 2^{nd} shell layer is not the same.

In some embodiments of the present invention, said 2^{nd} shell layer can be an alloyed shell layer.

In some embodiments of the present invention, the semiconducting light emitting nanoparticle can further comprise one or more additional shell layers onto the 2^{nd} shell layer as a multishell.

According to the present invention, the term “multishell” stands for the stacked shell layers consisting of three or more shell layers.

For examples, as a shell layer, CdS, CdZnS, CdS/ZnS, CdS, ZnS, ZnS/ZnSe, ZnSe/ZnS or combination of any of these can be used. Preferably, ZnS, ZnSe or ZnSe/ZnS.

For examples, as a semiconducting light emitting materials having core/shell structure, CdSe/CdS, CdSeS/CdZnS, CdSeS/CdS/ZnS, ZnSe/CdS, CdSe/ZnS, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS, InZnPS/ZnS, InZnPS/ZnSe, InZnPS/ZnSe/ZnS, ZnSe/CdS, ZnSe/ZnS or combination of any of these, can be used.

Preferably, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS.

Such semiconducting light emitting nanoparticles are publicly available (for example from Sigma Aldrich) and/or can be synthesized with the method described for example in U.S. Pat. Nos. 7,588,828 B, 8,679,543 B and Chem.

Mater. 2015, 27, pp 4893-4898.

### Organic Moiety

In a preferred embodiment of the present invention, the organic moiety is represented by following chemical formula (I);

A-B—* (I)
wherein
A is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
B is a connecting unit, preferably B is **—(U)ₒ—(Y)ₘ—(CR^{IIa}R^{IIb})ₙ, wherein “**” represents the connecting point to “A”; and
“*” represents the connecting point to the anion in the outer layer.

More preferably, the organic moiety is represented by following chemical formula (II), (III) or (III′);

L-(U)ₒ—(Y)ₘ—(CR^{IIa}R^{IIb})ₙ—* (II)
wherein
L is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
U is O, CH₂ or C═O;
Y is O, CH₂ or C═O;
R^{IIa} and R^{IIb} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIa} and R^{IIb} are hydrogen atom;
n is an integer 1 or more;
m is 0 or an integer 1 or more, preferably m is 1;
o is 0 or an integer 1 or more, preferably o is 1;
“*” represents the connecting point to the anion in the outer layer;

*—(CR^{IIIe}R^{IIIf})ₐ—(OCR^{IIIa}R^{IIIb}CR^{IIIc}R^{IIId})ₚ—(V)ᵣ—(CR^{IIIg}R^{IIIh})_{q}—Z (III)

*—(CR^{IIIg}R^{IIIh})_{q}—(V)ᵣ—(OCR^{IIIa}R^{IIIb}CR^{IIIc}R^{IIId})ₚ—Z (III′)
wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom; V is O, CH₂ or C═O;
Z is a hydrogen atom or an organic group, preferably Z is a hydrogen atom, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z is a hydrogen atom, a straight alkyl group having 1 to 25 carbon atoms, a branched alkyl group having 3 to 25 carbon atoms, more preferably it is a hydrogen atom, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1≤q≤5;
r is 0 or an integer 1;
“*” represents the connecting point to the anion in the outer layer.

Even more preferably, the organic moiety is represented by following chemical formula (IV):

*—(CR^{IIIe}R^{IIIf})ₐ—(OCR^{IIIa}R^{IIIb}CR^{IIIc}R^{IIId})p—(V)ᵣ—(CR^{IIIg}R^{IIIh})_{q}—Z′ (IV)
wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1;
V is O, CH₂ or C═O;
Z′ is a hydrogen atom a straight alkyl group having 1 to 25 carbon atoms, a branched alkyl group having 3 to 25 carbon atoms, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z′ is a straight alkyl group having 1 to 25 carbon atoms, a branched alkyl group having 3 to 25 carbon atoms or a hydrogen atom, more preferably it is a straight alkyl group having 1-15 carbon atoms, a branched alkyl group having 3-15 carbon atoms or a hydrogen atom, even more preferably it is a hydrogen atom;
r is 0 or an integer 1;
“*” represents the connecting point to the anion in the outer layer, preferably it is connected to S or Se atom in the outer layer.

In some of the preferred embodiments the organic moiety is CH₃—(CH₂)_{7<n<18-}* and connecting to the S or Se atom in the outer layer.

In a preferred embodiment of the present invention, the organic moiety selected from chemical formula (I), (II), (III), (III′) or (IV) is covalently bound to the anion in an inorganic lattice of the outer layer, preferably it is not removed by a ligand exchange.

Crystal bound ligands (covalently bound ligands) can be characterized as described in working example 7 and FIG. 4 of WO2020/216813 A1.

For examples, the organic moiety can be described as follows preferably.
—CH₂—(OCH₂CH₂)₄—O—CH₃
—CH₂—(OCH₂CH₂)₆—O—CH₃
—CH₂—(OCH₂CH₂)₈—O—CH₃
—(CH₂)₂—(OCH₂CH₂)₂—O—CH₃
—(CH₂)₂—(OCH₂CH₂)₆—O—CH₃
—(CH₂)₂—(OCH₂CH₂)₈—O—CH₃
—(CH₂)₂—(OCH₂CH₂)₆—CH₃
—(CH₂)₂—(OCH₂CH₂)₆—O—(CH₂)₂—SH
—(CH₂)₇—CH₃
—(CH₂)₁₁—CH₃
—(CH₂)₁₇—CH₃
—(CH₂)₂—(OCH₂CH₂)₁₆—O—CH₃
—(CH₂)₂—(OCH₂CH₂)₁₇—O—CH₃
“*” represents the connecting point to S atom or Se atom in the outer layer,
or
—(CH₂)₁₁—CH₃
“*” represents the connecting point to Se atom or S atom in the outer layer.

Other thiolated ligand materials like polypropyleneglycol and polypropyleneglycol monomethyl ether, thiolated ligand materials described in U.S. Ser. No. 11/021,651 B2, formula (I), formula (II) of column 17-18, line 28 of column 25 to line 16 of column 26, M1000-SH of Example 1 can also be used as a source of organic moiety and the resulting covalently bonded organic moiety is included in this patent application.

It is believed that the organic moiety prevents aggregation of nanoparticles or nanosized material, the organic moiety allows to disperse the nanoparticles in the organic medium and/or in aqueous medium.

Especially, it is believed that the organic moiety directly attached to the anion of the outer layer of the light emitting moiety by covalent bond can realize one or more of the technical effects of the present invention when it is mixed with the reactive monomer or a mixture of two or more reactive monomers of the present invention. Preferably said reactive monomer or two or more reactive monomers of the monomer mixture is a (meth)acrylate monomer(s). More preferably it is a specific (meth)acrylate monomer as defined in the section of reactive monomer below. It is believed that such specific combination of a light emitting moiety having covalently bonded organic moieties attached directly onto an outer layer of the light emitting moiety and specific (meth)acrylate monomer(s) can surprisingly improve thermal stability of an obtained layer (film), thermal stability of a light emitting moiety in a layer (film), dispersibility of a light emitting moiety in a composition, dispersibility of a light emitting moiety in an obtained layer enabling a phase separation of light emitting moiety and matrix material after curing realizing an improved haze value of the cured film (cured composition), long term Quantum Yield (QY) stability of a light emitting moiety in the composition in a longer term storage with or without light irradiation, long term External Quantum Efficiency (EQE) stability of a light emitting moiety in the composition in a longer term storage with or without light irradiation, long term Quantum Yield (QY) stability of a light emitting moiety in the obtained layer (film) in a longer term storage with or without light irradiation, long term External Quantum Efficiency (EQE) stability of a light emitting moiety in the obtained layer (film) in a longer term storage with or without light irradiation, good compatibility of light emitting moiety with a matrix material in a composition and/or an obtained layer (film), and/or realizing easy handling of a composition containing a light emitting moiety and a matrix material.

In some embodiments the organic moiety may comprise a zwitterionic group.

### Outer Layer

According to the present invention, the semiconducting nanoparticle comprises an outer layer covering at least a part of said core, comprising at least one metal cation and at least one divalent anion,
wherein said divalent anion is selected from Se²⁻, S²⁻, Te²⁻ O²⁻ or a combination of any of these, preferably said metal cation is a monovalent, divalent cation, trivalent or tetravalent cation, more preferably said metal cation is a divalent cation selected from the group consisting of Zn²⁺, Ni²⁺, Co²⁺, Ca²⁺, Sr²⁺, Fe²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺,

In some embodiments cation is monovalent cation selected from the group consisting of Cs⁺, Ag⁺, Au⁺, Cu⁺¹ or a divalent cation selected from the group consisting of Zn²⁺, Fe⁺², Ni²⁺, Co²⁺, Ca²⁺, Sr²⁺, Hg²⁺, Mg²⁺ and Pb²⁺, Cu⁺² or a trivalent cation selected from the group Fe⁺³, In⁺³, Bi⁺³, Ga⁺³ a tetravalent cation selected from the group consisting of Ti⁴⁺, Ge⁴⁺, Si⁴⁺, Zr⁴⁺, Hf⁴⁺, and Sn⁴*, Si⁺⁴.

In some embodiments of the present invention, said outer layer comprises at least two or three different metal cations such as the combination of Cu¹⁺ and In³⁺, Cu¹⁺ and Ga³⁺, Ag¹⁺ and Ga³⁺ or a combination of Cu⁺¹/In⁺³/Zn⁺² or a combination of Cu⁺¹/Ga⁺³/Zn⁺² or a combination of Cu⁺¹/In⁺³/Ga⁺³/Zn⁺² or a combination of Cu⁺¹/In⁺³/Ga⁺³.

In a preferred embodiment, the metal cation is a divalent cation selected from the group consisting of Fe⁺² Zn²⁺, Ni²⁺, Co²⁺, Ca²⁺, Sr²⁺, Hg²⁺, Mg²⁺ and Pb²⁺, Cu⁺².

In a preferred embodiment of the present invention, said outer layer comprising, essentially consisting of, or consisting of a material represented by following chemical formula (VI),

QP₁₋₂ₕAₕ (VI)
wherein Q is a divalent anion selected from one or more members of the group consisting of Se²⁻, S²⁻, Te²⁻ and O²⁻;
P is a divalent metal cation, preferably P is a divalent cation selected from one or more member of the group consisting of Zn²⁺, Ni²⁺, Co²⁺, Ca²⁺, Sr²⁺, Hg²⁺, Mg²⁺ and Pb²⁺;
A is a tetravalent cation, preferably A is selected from one or more members of the group consisting of Ti⁴⁺, Ge⁴⁺, Si⁴⁺, and Sn⁴⁺; and 0≤h≤0.5.

For examples, ZnS, ZnSe, ZnSeS, ZnTe, ZnO, ZnNiS, ZnNiSe, ZnGeS, ZnGeO, ZnCaS, NiSe, TiGeSeS, ZnTiS, CuInZnS, CuInZnSe, AgInZnS, and/or AgInZnSe can be used.

According to the present invention, preferably said outer layer is a monolayer.

More preferably, it is a last monolayer of the semiconducting nanoparticle covering the core. In case there is one or more of shell layers covering the core, then the outer layer is covering the shell layers.

In some embodiments of the present invention, the concentration of Se in the shell layer varies from a high concentration of the first semiconducting nanoparticle side in the shell layer to a low concentration of the opposite side in the shell layer, more preferably, the concentration of S in the shell layer varies from a low concentration of first semiconducting nanoparticle side of the shell layer to a higher concentration to the opposite side of the shell layer, the concentration of Te in the shell layer varies from a high concentration of first semiconducting nanoparticle side of the shell layer to a lower concentration to the opposite side of the shell layer.

In some embodiments of the present invention, the surface of the light emitting moiety, namely a semiconducting light emitting nanoparticle can be over coated with one or more kinds of surface ligands in addition to the organic moiety of the present invention.

Without wishing to be bound by theory it is believed that such surface ligands may lead to disperse the nanosized fluorescent material in a solvent more easily.

The surface ligands in common use include phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), amines such as Oleylamine, Dodecyl amine (DDA), Tetradecyl amine (TDA), Hexadecyl amine (I), and Octadecyl amine (ODA), Oleylamine (OLA), 1-Octadecene (ODE); thiols, when organic moiety of thiol may include linear or branched alkyl chain which can be saturated or include one or more unsaturated carbon bonds and/or aromatic rings, such as octadecane thiol, hexadecane thiol, dodecane thiol, hexane thiol and polyethylene glycol thiols; selenols, when organic moiety of selenol may include linear or branched alkyl chain which can be saturated or include one or more unsaturated carbon bonds and/or aromatic rings; mercapto carboxylic acids such as mercapto propionic acid and mercaptoundecanoicacid; carboxylic acids such as oleic acid, stearic acid, myristic acid, isostearic acid; acetic acid and a combination of any of these. Furthermore, the ligands can include Zn-oleate, Zn-acetate, Zn-myristate, Zn-Stearate, Zn-laurate and other Zn-carboxylates, Zn-isostearate, sulfonic acids, halides, carbamates.

Examples of surface ligands have been described in, for example, the laid-open international patent application No. WO 2012/059931A.

### Measurement of Quantum Yield

According to the present invention the Quantum Yield of the quantum dots (QY) is measured using Hamamatsu absolute quantum yield spectrometer (model: Quantaurus C11347).

Preferably, the nanoparticle emits light having the peak maximum light emission wavelength in the range from 350 nm 3500 nm, preferably from 350 nm to 2000 nm, more preferably from 400 nm to 800 nm, even more preferably from 430 nm to 700 nm.

In a preferable embodiment, the total amount of the light emitting moiety is in the range from 0.1 wt. % to 90 wt. % based on the total amount of the composition, preferably from 10 wt. % to 70 wt. %, more preferably from 30 wt. % to 50 wt. %.

### Reactive Monomer

It is believed that the lower viscosity is important to make a low viscosity composition suitable for inkjet printing. Therefore, a (meth)acrylate monomer having the viscosity value within the above-mentioned parameter ranges are especially suitable to make a composition for inkjet printing. By using these (meth)acrylate monomer in a composition, when it is mixed with another material such as semiconducting light emitting nanoparticles with high loading, the composition can still keep lower viscosity within the range suitable for inkjet printing.

Further, it is believed that a combination of the reactive monomer or a mixture of two or more reactive monomers, preferably a (meth)acrylate monomer or a mixture of two or more (meth)acrylate monomers of the present invention, and the light emitting moiety comprising an outer layer containing a metal cation and a divalent anion, and one or more types of organic moieties directly attached to the anion of the outer layer by covalent bond, may specifically improve optical performance of the light emitting moiety in an obtained layer (film).

It is also believed that said combination may also lead improve thermal stability of an obtained layer (film), thermal stability of a light emitting moiety in a layer (film), dispersibility of a light emitting moiety in a composition, dispersibility of a light emitting moiety in an obtained layer enabling a phase separation of light emitting moiety and matrix material after curing realizing an improved haze value of the cured film (cured composition), long term Quantum Yield (QY) stability of a light emitting moiety in the composition in a longer term storage with or without light irradiation, long term External Quantum Efficiency (EQE) stability of a light emitting moiety in the composition in a longer term storage with or without light irradiation, long term Quantum Yield (QY) stability of a light emitting moiety in the obtained layer (film) in a longer term storage with or without light irradiation, long term External Quantum Efficiency (EQE) stability of a light emitting moiety in the obtained layer (film) in a longer term storage with or without light irradiation, good compatibility of light emitting moiety with a matrix material in a composition and/or an obtained layer (film), and/or realizing easy handling of a composition containing a light emitting moiety and a matrix material.

In a preferred embodiment of the present invention, the boiling point (B.P.) of said reactive monomer is 95 °C or more, preferably it is in the range from 95 °C to 350 °C, for large area uniform inkjet printing.

It is believed that said high boiling point is also important to make a composition having a lower vapor pressure preferably less than 0.001 mmHg for large area uniform printing, it is preferable to use a reactive monomer, preferably a (meth)acrylate monomer, more preferably a (meth)acrylate monomer of formula (I), (II) and/or (III) having the viscosity value of 25 cP or less at 25 °C and the boiling point at least 95 °C or more, preferably it is in the range from 95 °C to 350 °C, to make a composition suitable for large area uniform inkjet printing even if it is mixed with high loading of another materials such as high loading of semiconducting light emitting nanoparticles.

Here, the term “(meth)acrylate” is a general term for an acrylate and a methacrylate. Therefore, according to the present invention, the term “(meth)acrylate monomer” means a methacrylate monomer and/or an acrylate monomer.

According to the present invention, said B.P can be estimate by the known method such as like described in Science of Petroleum, Vol. II. p. 1281 (1398).

According to the present invention, any types of publicly available acrylates and/or methacrylates represented by chemical formula (I) or (II) can be used preferably.

Especially for the first aspect, any types of publicly available acrylates and/or methacrylates having the viscosity value of 25 cP or less at 25 °C represented by chemical formula (I), (II) and/or (III) can be used.

Thus, according to the present invention, the reactive monomer of the composition is preferably a (meth)acrylate monomer selected from a mono-(meth)acrylate monomer, a di-(meth)acrylate monomer and/or a tri-(meth)acrylate monomer.

Preferably said reactive monomers of the monomer mixture is each independently selected from a mono-(meth)acrylate monomer, a di-(meth)acrylate monomer and/or a tri-(meth)acrylate monomer.

Preferably, said di-(meth)acrylate monomer is represented by following chemical formula (I^{b}), said mono-acrylate monomer is represented by following chemical formula (II^{b}) and/or said tri-(meth)acrylate monomer is represented by following chemical formula (III^{b});

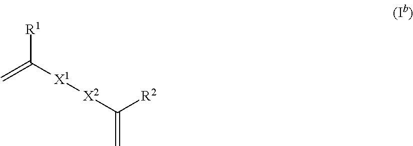

wherein
X¹ is an ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said alkyl group has carbon atoms 1 to 45, preferably said aryl group has carbon atoms 3 to 45;
preferably said ester group is represented by following formula (I^{bs1});

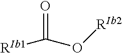

wherein R^{Ib1} is a single bond, a non-substituted or substituted alkylene chain having carbon atoms 1 to 5;
R^{Ib2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
X² is an ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂;
preferably said alkyl group has carbon atoms 1 to 45, preferably said aryl group has carbon atoms 3 to 45;
preferably said ester group is represented by following formula (I^{bs2});

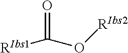

wherein R^{Ibs1} is a single bond, a non-substituted or substituted alkylene chain having carbon atoms 1 to 5;
R^{Ibs2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R¹ is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group; preferably said alkyl group has carbon atoms 1 to 45, preferably said aryl group has carbon atoms 3 to 45;
R² is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group; preferably said alkyl group has carbon atoms 1 to 45, preferably said aryl group has carbon atoms 3 to 45;

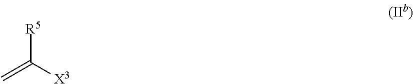

R⁵ is a hydrogen atom, halogen atom of Cl, Br, or F, methyl group, alkyl group, aryl group, alkoxy group, ester group, or a carboxylic acid group;
X³ is an ester group, alkyl group, cyclo-alkyl group, aryl group or an alkoxy group, in case of X³ is an ester group, said ester group is represented by following formula (II^{bs});

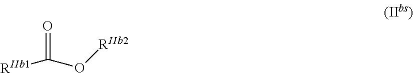

wherein R^{IIb1} is a single bond, a non-substituted or substituted alkylene chain having carbon atoms 1 to 5;
R^{IIb2} is a substituted or non-substituted alkyl group, cyclo group, cyclo-alkyl group, aryl group or an alkoxy group;
preferably the symbol X³ is

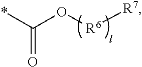

where “*” on the left side of the formula represents the connecting point to the end group C═CR⁵ of the formula (I);
I is 0 or 1;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another.

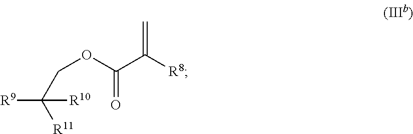

wherein R⁹ is hydrogen atom, a straight alkyl group having 1 to 25 carbon atoms or a (meth)acryl group represented by chemical formula (IV^{b})

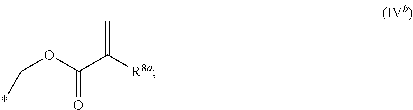

R¹⁰ is hydrogen atom, a straight alkyl group having 1 to 25 carbon atoms or a (meth)acryl group represented by chemical formula (V^{b})

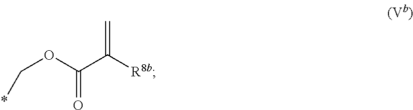

R¹¹ is hydrogen atom, a straight alkyl group having 1 to 25 carbon atoms or a (meth)acryl group represented by chemical formula (VI^{b})

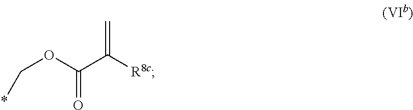

wherein R⁸, R^{8a}, R^{8b} and R^{8c} are, each independently or dependently of each other at each occurrence, H, CH₃ or CH₂CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹² to 1.0*10⁻¹⁵.

More preferably, said reactive monomer is represented by the chemical formula (II).

In a preferable embodiment, the monomer mixture of the composition comprises a(meth)acrylate monomer of chemical formula (II) and another (meth)acrylate monomer selected from the (meth)acrylate monomer of chemical formula (I) and/or a (meth)acrylate monomer of chemical formula (III).

In a preferred embodiment of the present invention, the (meth)acrylate monomer of chemical formula (II) is in the composition and the mixing ratio of the (meth)acrylate monomer of chemical formula (I) to the (meth)acrylate monomer of chemical formula (II) is in the range from 1:99 to 99:1 (formula (I):formula (II)), preferably from 5:95 to 50:50, more preferably from 10:90 to 40:60, even more preferably it is from 15:85 to 40:60, preferably at least a purified (meth)acrylate monomer represented by chemical formula (I), (II) is used in the composition, more preferably the (meth)acrylate monomer of chemical formula (I) and the (meth)acrylate monomer of chemical formula (II) are both obtained or obtainable by a purification method.

In a preferred embodiment, the boiling point (B.P.) of said (meth)acrylate monomer of chemical formula (I) and/or chemical formula (II) is 95 °C or more, preferably the (meth)acrylate monomers of chemical formula (I) and chemical formula (II) are both 100 °C or more, more preferably it is in the range from 100 °C to 350 °C, even more preferably the boiling point (B.P.) of the (meth)acrylate monomers of chemical formula (I) is in the range from 100 °C to 300 °C and the boiling point (B.P.) of the (meth)acrylate monomers of chemical formula (II) is in the range from 150 °C to 320 °C.

In a preferred embodiment of the present invention, the viscosity of the composition is 35 cP or less at room temperature, preferably in the range from 1 to 35 cP, more preferably from 2 to 30 cP, even more preferably from 2 to 25 cP.

According to the present invention, said viscosity can be measured by vibration type viscometer VM-10A (SEKONIC) at room temperature. https://www.sekonic.co.jp/english/product/viscometer/vm/vm_series.html

### (Meth)Acrylate Monomer Represented by Chemical Formula (I) as a Matrix Material

Furthermore preferably, R^{Ib1} of (I^{bs1}) is a single bond, R^{Ibs1} of (I^{bs2}) is a single bond, R^{Ib2} of (I^{bs1}) is a non-substituted or substituted branched alkylene chain having carbon atoms 3 to 7, R^{Ibs2} is a single bond, a non-substituted straight alkylene chain having carbon atoms 1 to 5, a non-substituted branched alkylene chain having carbon atoms 3 to 7, where one or more non-adjacent CH₂ groups may be replaced by oxygen atom, or said R³ of formula (I) and R⁴ of formula (I) are, each independently of each other, selected from the following groups.

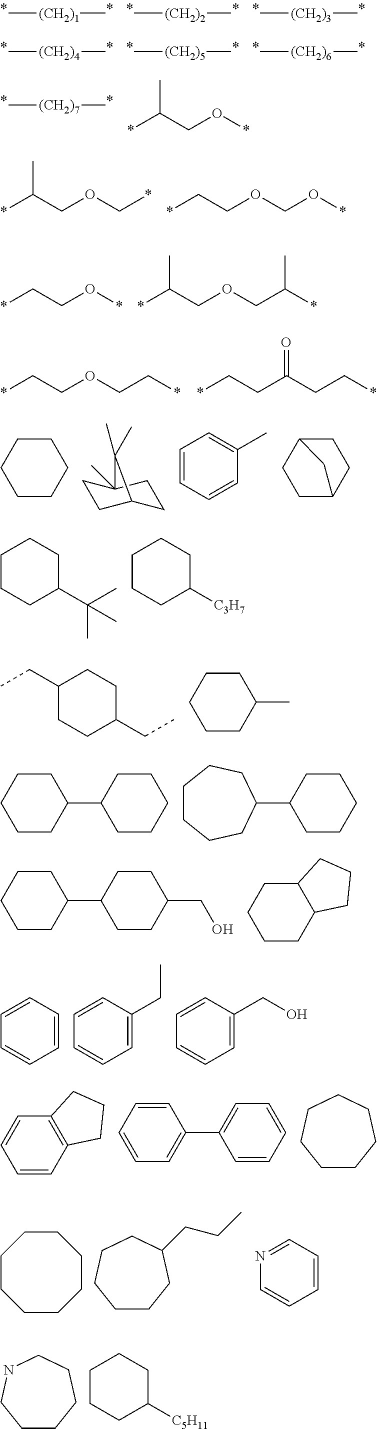

Particularly preferably, said R³ and R⁴ of formula (I) are, at each occurrence, independently or differently, selected from the following groups.

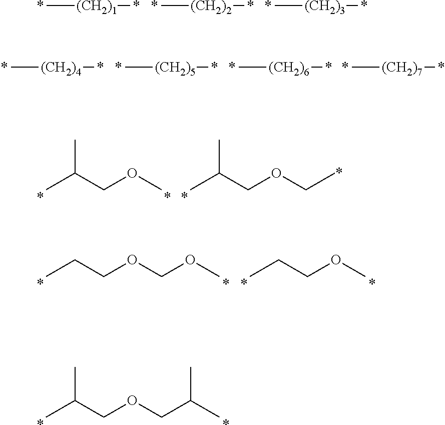

wherein “*” represents the connecting point to oxygen atom of the formula or the connecting point to X² of the formula in case of R³, and wherein represents the connecting point to oxygen atom of the formula or the connecting point to X¹ of the formula in case of R⁴.

Particularly preferably, said formula (I) is NDDA (nonanediol diacrylate), HDDMA (hexanediol dimethacrylate), HDDA (hexanediol diacrylate) or DPGDA (di-propyleneglycol di-acrylate).

### (Meth)Acrylate Monomer Represented by Chemical Formula (II)

It is believed that the (meth)acrylate monomer represented by following chemical formula (II) shows much lower viscosity value than the viscosity of the (meth)acrylate monomer of formula (I). Thus, by using the (meth)acrylate monomer represented by chemical formula (II) in combination of the (meth)acrylate monomer of chemical formula (I), a composition having much lower viscosity desirable for smooth inkjet printing can be realized, preferably without decreasing External Quantum Efficiency (EQE) value.

It is believed that said combination can realize a low viscosity composition comprising high amount of another materials, such as high loading of light emitting moieties especially, semiconducting light emitting nanoparticles.

Thus, it is especially suitable for an inkjet printing when the composition comprises higher amount of light emitting moieties.

Furthermore preferably, R^{IIb1} of (II^{bs}) is a single bond, R^{IIb2} of (II^{bs}) is a substituted or non-substituted alkyl group, cyclo group, cyclo-alkyl group; R^{IIb2} of (II^{bs}) can be selected from the following groups.

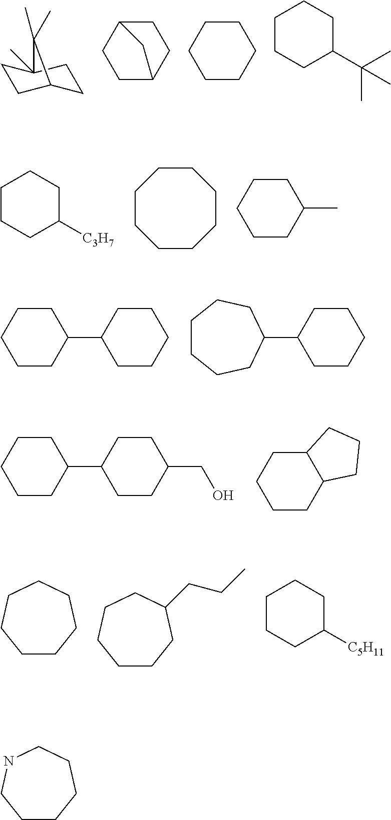

or said R⁷ of formula (II) is, at each occurrence, independently or differently, selected from the following groups, wherein the groups can be substituted with R^{a}, preferably they are unsubstituted by R^{a}.

| | | |
|---|---|---|
| *—(CH₂)₆—CH₃ | *—(CH₂)₇—CH₃ | *—(CH₂)₈—CH₃ |
| *—(CH₂)₉—CH₃ | *—(CH₂)₁₀—CH₃ | *—(CH₂)₁₁—CH₃ |
| *—(CH₂)₁₂—CH₃ | *—(CH₂)₄—OH | *—(CH₂)₂—OH |
| *—(CH₂)₆—OH | *—(CH₂)₃—OH | *—(CH₂)₅—OH |

wherein “*” represents the connecting point to R⁶ of X³ in case I is 1, and it is representing the connecting point to oxygen atom of X³ of the formula (II) in case n is 0.

Particularly preferably, said formula (II) is Lauryl methacrylate (LM, viscosity 6 cP) or Lauryl acrylate (LA, viscosity: 4.0 cP) or isobornyl acrylate (IBOA).

It is believed that the higher amount of the (meth)acrylate monomer of chemical formula (II) to the total amount of the (meth)acrylate monomer of chemical formula (I) leads improved EQE of the composition, and the mixing weight ratio of the (meth)acrylate monomer of chemical formula (II) to the total amount of the (meth)acrylate monomer of chemical formula (I) more than 50 wt. % is preferable from the view point of viscosity of the composition, better ink-jetting properties of the composition.

Preferably, (meth)acrylate monomers purified by using silica column are used.

It is believed that an impurity removal from the (meth)acrylate monomers by the silica column purification leads improved QY of the semiconducting light emitting nanoparticle in the composition.

### (Meth)Acrylate Monomer of Chemical Formula (III)

It is believed that the (meth)acrylate monomer of chemical formula (III) is useful to improve its solidity of a later made from the composition after inkjet printing.

According to the present invention, a publicly known a (meth)acrylate monomer represented by following chemical formula (III) can be used to improve solidity of a layer after inkjet printing and cross linking.

Very preferably, Trimethylolpropane Triacrylate (TMPTA) is used as the (meth)acrylate monomer of chemical formula (III).

In a preferable embodiment of the present invention, the amount of the (meth)acrylate monomer of chemical formula (III) based on the total amount of (meth)acrylate monomers in the composition is in the range from 0.001 wt. % to 25 wt. %, more preferably in the range from 0.1 wt. % to 15 wt. %, even more preferably from 1 wt. % to 10 wt. %.

Preferably, there (meth)acrylate monomers are purified by using silica column, are used.

It is believed that an impurity removal from the (meth)acrylate monomers by the silica column purification leads improved QY of the semiconducting light emitting nanoparticle in the composition.

### Further Embodiments of the Composition

### Another Materials

According to the present invention, preferably, comprises an another material selected from one or more members of the group consisting of; another light emitting moiety which is different from the light emitting moiety of the present invention; scattering particles, anti-oxidants, radical quenchers, a photo initiators and surfactants. As said another material, publicly known one can be used.

### Solvents

In a preferable embodiment of the present invention, the composition comprises a solvent 10 wt % or less based on the total amount of the composition, more preferably it is 5 wt % or less, more preferably it is a solvent free composition, preferably said composition does not comprise any one of the following solvent selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether (PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, triethylene glycol and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, trimethyl benzenes such as 1,3,5-trimethylbenzene, 1,2,4-trimethyl benzene, 1,2,3-trimethyl benzene, docecylbenzene, cyclohexylbenzene, 1,2,3,4-tetramethylbenzene, 1,2,3,5-tetramethylbenzene, 3-isopropylbiphenyl, 3-methylbiphenyl, 4-methylbiphenyl and dichlorobenzene, preferably said solvent is propylene glycol alkyl ether acetates, alkyl acetates, ethylene glycol monoalkyl ethers, propylene glycol, and propylene glycol monoalkyl ethers.

### Process for Preparing the Composition

In another aspect, the present invention also relates to a process for preparing the composition comprising at least, essentially consisting of or consisting of, following steps,
(a) mixing a light emitting moiety, at least one reactive monomer or a mixture of two or more reactive monomers and a chemical compound represented by following chemical formula (X^{a}) to from a composition.

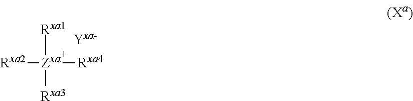

where symbols R^{xa1}, R^{xa1}, R^{xa1}, R^{xa1} Z^{xa}, Y^{xa-} are as defined in the section “chemical compound represented by following chemical formula (X^{a})”.

Optionally, a thiol containing chemical compound and/or a chemical compound as defined in the section of “thiol containing chemical compound” and “mPEG thiol like chemical compound” above is (are) added in step (a). Optionally, one or more another materials as defined in the section of “another material” above can be added.

### Composition Made by the Process

In another aspect, the present invention further relates a composition obtainable or obtained from the process above.

### Use

In another aspect, the present invention also relates to use of the composition in an electronic device, optical device, sensing device or in a biomedical device.

### Method for Forming a Layer

In another aspect, the present invention also relates to a method for forming a layer comprising:
S1) providing the composition onto a substrate, preferably by ink-jetting;
S2) curing the composition, preferably said curing is a photo curing performed by photo irradiation, thermal curing or a combination of a photo curing and a thermal curing.

### Layer

In another aspect, the present invention also relates to a layer obtained or obtainable from the method of the present invention.

In another aspect, the present invention also relates to a layer containing at least, essentially consisting of or consisting of;
Xi) a light emitting moiety, preferably it is a semiconducting light emitting nanoparticle; where the details of the light emitting moiety is already described above.
Xii) a polymer made from at least one reactive monomer or a mixture of two or more reactive monomers, preferably said monomer having one or more of functional groups, more preferably it is a(meth)acrylate monomer;
Xiii) a chemical compound represented by following chemical formula (X^{a})

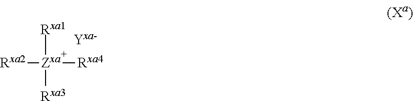

where symbols R^{xa1}, R^{xa1}, R^{xa1}, R^{xa1} Z^{xa}, Y^{xa-} are as defined in the section “chemical compound represented by following chemical formula (X^{a})”.

Optionally, a thiol containing chemical compound and/or a chemical compound as defined in the section of “thiol containing chemical compound” and “mPEG thiol like chemical compound” above is (are) included. Optionally, one or more another materials as defined in the section of “another material” above is included.

### Color Conversion Device (100)

In another aspect, the present invention also relates to a color conversion device (100) comprising at least, essentially consisting of or consisting of, a 1^{st} pixel (161) partly or fully filled with the layer comprising at least a matrix material (120) containing a light emitting moiety (110), and a bank (150) comprising at least a polymer material, preferably the color conversion device (100) further contains a supporting medium (170).

### 1^{st} Pixel (161)

According to the present invention, said 1^{st} pixel (161) comprises at least a matrix material (120) containing a light emitting moiety (110). In a preferable embodiment, the 1^{st} pixel (161) is a solid layer obtained or obtainable by curing the composition of the present invention containing at least one acrylate monomer together with at least one light emitting moiety (110), preferably said curing is a photo curing by photo irradiation, thermal curing or a combination of a photo curing and a thermal curing.

In some embodiments of the present invention, the layer thickness of the pixel (161) is in the range from 0.1 to 100 μm, preferably it is from 1 to 50 μm, more preferably from 5 to 25 μm.

In some embodiments of the present invention, the color conversion device (100) further contains a 2^{nd} pixel (162), preferably the device (100) contains at least said 1^{st} pixel (161), 2^{nd} pixel (162) and a 3^{rd} pixel (163), more preferably said 1^{st} pixel (161) is a red color pixel, the 2^{nd} pixel (162) is a green color pixel and the 3^{rd} pixel (163) is a blue color pixel, even more preferably the 1^{st} pixel (161) contains a red light emitting moiety (110R), the 2^{nd} color pixel (162) contains a green light emitting moiety (110G) and the 3^{rd} pixel (163) does not contain any light emitting moiety.

In some embodiments, at least one pixel (160) additionally comprises at least one light scattering particle (130) in the matrix material (120), preferably the pixel (160) contains a plurality of light scattering particles (130).

In a preferable embodiment, said 1^{st} pixel (161) consists of one pixel or two or more sub-pixels configured to emit red-color when irradiated by an excitation light, more preferably said sub-pixels contains the same light emitting moiety (110).

### Matrix Material (120)

In a preferable embodiment, the matrix material (120) contains a (meth)acrylate polymer, preferably it is a methacrylate polymer, an acrylate polymer or a combination of thereof, more preferably it is an acrylate polymer, even more preferably said matrix material (120) is obtained or obtainable from the composition of the present invention containing at least one acrylate monomer, further more preferably said matrix material (120) is obtained or obtainable from the composition of the present invention containing at least one di-acrylate monomer, particularly preferably said matrix material (120) is obtained or obtainable from the composition of the present invention containing at least one di-acrylate monomer and a mono-acrylate monomer, preferably said composition is a photosensitive composition.

### Bank (150)

In some embodiments of the present invention, the height of the bank (150) is in the range from 0.1 to 100 μm, preferably it is from 1 to 50 μm, more preferably from 1 to 25 μm, furthermore preferably from 5 to 20 μm.

In a preferred embodiment of the present invention, the bank (150) is configured to determine the area of said 1^{st} pixel (161) and at least a part of the bank (150) is directly contacting to at least a part of the 1^{st} pixel (161), preferably said 2^{nd} polymer of the bank (150) is directly contacting to at least a part of the 1^{st} polymer of the 1^{st} pixel (161).

More preferably, said bank (150) is photolithographically patterned and said 1^{st} pixel (161) is surrounded by the bank (150), preferably said 1^{st} pixel (161), the 2^{nd} pixel (162) and the 3^{rd} pixel (163) are all surrounded by the photolithographically patterned bank (150).

### Method for Fabricating a Color Conversion Device (100)

In another aspect, the present invention also relates to a method for fabricating a color conversion device (100) of the present invention, containing at least the following steps, preferably in this sequence,
Xi) Providing a bank composition onto a surface of a supporting medium
Xii) Curing the bank composition,
Xiii) Applying photo-patterning to the cured said composition to fabricate bank and a patterned pixel region,
Xiv) Providing the composition of the present invention to at least one pixel region, preferably by ink-jetting,
Xv) Curing the composition, preferably said color conversion device (100) further contains a supporting medium (170).

In another aspect, the present invention further relates to a color conversion device (100) obtainable or obtained from the method of the present invention.

In another aspect, the present invention further relates to use of the color conversion device (100) of the present invention in an optical device (300) containing at least one functional medium (320, 420, 520) configured to modulate a light or configured to emit light.

### Optical Device

Further, in another aspect, the present invention further relates to an optical device (300) containing at least, essentially consisting of or consisting of, one functional medium (320, 420, 520) configured to modulate a light or configured to emit light, and a layer or the color conversion device (100) of the present invention.

In some embodiments of the present invention, said optical device can be a liquid crystal display device (LCD), Organic Light Emitting Diode (OLED), Light Emitting Diode device (LED), Micro LED, Micro Electro Mechanical Systems (here in after “MEMS”), electro wetting display, or an electrophoretic display.

Therefore, in a preferred embodiment, said functional medium can be a LC layer, OLED layer, LED layer, micro LED layer, MEMS layer, electro wetting layer and/or an electrophoretic layer. More preferably it is a LC layer, micro LED layer or an OLED layer.
Light emitting moiety, semiconducting light emitting material having a ligand derived from formula (X^{a})

In another aspect, the present invention may further relate to a light emitting moiety, preferably it is a semiconducting light emitting material as defined in the specification, comprising a 1^{st} ligand derived from the chemical compound represented by following chemical formula (X^{a}) as defined in the specification. Optionally, said light emitting moiety further contains a 2nd ligand derived from the thiol containing chemical compound is represented by chemical formula (P^{XA}) as defined in the specification. Furthermore preferably, said light emitting moiety further contains a chemical compound comprising at least one group selected from the group consisting of straight-chain alkyl group having carbon atoms 1 to 80 or branched-chain alkyl group having carbon atoms 3 to 80, straight-chain aryl-alkyl group having carbon atoms 5 to 45, branched-chain aryl-alkyl group having carbon atoms 6 to 45, straight-chain cyclo-alkyl group having carbon atoms 4 to 45; and branched-chain cyclo-alkyl group having carbon atoms 6 to 45, where one or more non-adjacent CH₂ groups of the above mentioned groups is replaced by oxygen atom, C═O, C═S, C═Se, C═NH, SiH₂, SO, SO₂, OS, or CONH and where one or more H atoms may be replaced by D, F, Cl, Br, I, CN or NO₂; preferably the molecular weight of said chemical compound is 2000 or less, more preferably 1000 or less, even more preferably 500 or less and the molecular weight of said chemical compound is preferably 100 or more, more preferably 200 or more, even more preferably 300 or more, preferably said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid as defined in the specification. Optionally, said light emitting moiety further comprises an outer layer containing a metal cation and a divalent anion; and
one or more types of organic moieties directly attached to the anion of the outer layer by covalent bond,
wherein said divalent anion of the outer layer is selected from Se²⁻, S²⁻, Te²⁻ O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺ as already defined in the specification. More details of the outer layer and the organic moiety is defined in the specification. Said light emitting moiety can be used in the composition of the present invention and can be included in the layer of the present invention in addition to or instead of the light emitting moiety of the composition of the present invention.

### Preferable Embodiments

1. A composition, preferably it is being of a photocurable composition, comprising at least;
i) a light emitting moiety, preferably it is a semiconducting light emitting nanoparticle,
ii) at least one reactive monomer or a mixture of two or more reactive monomers, preferably said monomer having one or more of functional groups, more preferably it is a (meth)acrylate monomer; and
iii) a chemical compound represented by following chemical formula (X^{a}).

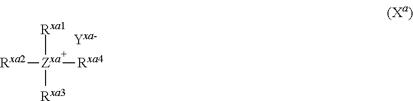

wherein
R^{xa1}, R^{xa1}, R^{xa1}, R^{xa1} are each independently of each other, selected from straight chain alkyl group having 1-25 carbon atoms, preferably 1 to 15 carbon atoms; a branched or cyclic alkyl group having 3-25 carbon atoms, preferably 3-15 carbon atoms; a straight-chain alkenyl or alkynyl group having 2 to 25 carbon atoms, preferably 2 to 15 carbon atoms; a branched alkenyl group or alkynyl group having 3 to 25 carbon atoms, preferably 3 to 15 carbon atoms; an aromatic or heteroaromatic ring system having 5 to 25 aromatic ring atoms, preferably 5 to 15 aromatic ring atoms; each of which may be substituted by one or more groups R^{a},
R^{a} is at each occurrence, identically or differently, H, D, a straight chain alkyl or alkoxy group having 1 to 40 carbon atoms, preferably 1 to 25 carbon atoms, more preferably 1 to 15 carbon atoms; a branched or cyclic alkyl or alkoxy group having 3 to 40 carbon atoms, preferably 3 to 25 carbon atoms, more preferably 3 to 15 carbon atoms; a straight-chain alkenyl or alkynyl group having 2 to 40 carbon atoms, preferably 2 to 24 carbon atoms, more preferably 2 to 12 carbon atoms; a branched alkenyl group or alkynyl group having 3 to 40 carbon atoms, preferably 3 to 24 carbon atoms, more preferably 3 to 12 carbon atoms; an aromatic or heteroaromatic ring system having 5 to 40 aromatic ring atoms, preferably 5 to 25 aromatic ring atoms, more preferably 5 to 18 aromatic ring atoms, wherein in each of the above-mentioned groups one or more H atoms may be replaced by D, F, Cl, Br, I, and where two or more adjacent substituents R^{a} here may optionally form a mono- or polycyclic, aliphatic ring system with one another;
Z^{xa} is N, P or As, preferably it is N or P, more preferably N;
Y^{xa-} is a halogen containing monovalent anion, preferably it is selected from the group consisting of F⁻, Cl⁻, Br⁻, I⁻, At⁻, Ts⁻, BF⁴⁻, PF⁶⁻, more preferably it is F⁻, Cl⁻, Br⁻, I⁻, BF⁴⁻, PF⁶⁻, even more preferably it is Br⁻, F⁻, Cl⁻ furthermore preferably it is Br⁻.
2. The composition of embodiment 1, wherein R^{xa1}, R^{xa1}, R^{xa1}, R^{xa1} of the chemical formula (X^{a}) are each independently of each other, selected from straight chain alkyl group having 1-25 carbon atoms, preferably 1 to 15 carbon atoms; a branched or cyclic alkyl group having 3-25 carbon atoms, preferably 3-15 carbon atoms; a straight-chain alkenyl or alkynyl group having 2 to 25 carbon atoms, preferably 2 to 15 carbon atoms; a branched alkenyl group or alkynyl group having 3 to 25 carbon atoms, preferably 3 to 15 carbon atoms; each of which may be substituted by one or more groups R^{a}, more preferably R^{xa1}, R^{xa1}, R^{xa1}, R^{xa1} are each independently of each other, selected from straight chain alkyl group having 1-25 carbon atoms, preferably 1 to 15 carbon atoms; a branched alkyl group having 3-25 carbon atoms, preferably 3-15 carbon atoms; each of which may be substituted by one or more groups R^{a};
Z^{xa} is N, P or As, preferably it is N or P, more preferably N;
Y^{xa-} is a halogen containing monovalent anion, preferably it is selected from the group consisting of F⁻, Cl⁻, Br⁻, I⁻, At⁻, Ts⁻, BF⁴⁻, PF⁶⁻, more preferably it is F⁻, Cl⁻, Br⁻, I⁻, BF⁴⁻, PF⁶⁻, even more preferably it is Br⁻, F⁻, Cl⁻ furthermore preferably it is Br⁻.
3. The composition of embodiment 1 or 2, wherein the total amount of the chemical compound of chemical formula (X^{a}) is in the range from 0.001 to 2.0 wt % based on the total amount of the composition without solvent, preferably it is in the range from 0.01 to 1.9 wt %, more preferably from 0.02 to 1.8 wt %, even more preferably 0.03 to 1.6 wt %, furthermore preferably 0.04 to 1.4 wt %.
4. The composition of any one of embodiments 1 to 3, further comprises a thiol containing chemical compound. Preferably the total amount of the thiol containing chemical compound is in the range from 0.1 to 20 wt % based on the total amount of the composition without solvent, more preferably it is 1 to 15 wt %, even more preferably it is 5 to 10 wt %. Preferably it is represented by following chemical formula (P^{XA}).

R^{xa1}—SH (P^{XA})
wherein
R^{xa1} is selected from a straight chain alkyl group having 1-40 carbon atoms, preferably 5 to 30 carbon atoms; a branched or cyclic alkyl group having 3-40 carbon atoms, preferably 5-30 carbon atoms; a straight-chain alkenyl or alkynyl group having 2 to 40 carbon atoms, preferably 5 to 30 carbon atoms; a branched alkenyl group or alkynyl group having 3 to 40 carbon atoms, preferably 5 to 30 carbon atoms; an aromatic or heteroaromatic ring system having 5 to 40 aromatic ring atoms, preferably 5 to 30 aromatic ring atoms; each of which may be substituted by one or more groups R^{a},
R^{a} is at each occurrence, identically or differently, H, D, a straight chain alkyl or alkoxy group having 1 to 40 carbon atoms, preferably 1 to 25 carbon atoms, more preferably 1 to 15 carbon atoms; a branched or cyclic alkyl or alkoxy group having 3 to 40 carbon atoms, preferably 3 to 25 carbon atoms, more preferably 3 to 15 carbon atoms; a straight-chain alkenyl or alkynyl group having 2 to 40 carbon atoms, preferably 2 to 24 carbon atoms, more preferably 2 to 12 carbon atoms; a branched alkenyl group or alkynyl group having 3 to 40 carbon atoms, preferably 3 to 24 carbon atoms, more preferably 3 to 12 carbon atoms; an aromatic or heteroaromatic ring system having 5 to 40 aromatic ring atoms, preferably 5 to 25 aromatic ring atoms, more preferably 5 to 18 aromatic ring atoms, wherein in each of the above-mentioned groups one or more H atoms may be replaced by D, F, Cl, Br, I, and where two or more adjacent substituents R^{a} here may optionally form a mono- or polycyclic, aliphatic ring system with one another. Preferably, the sum of the total amount of chemical compound of chemical formula (X^{a}) of embodiment 3 and the total amount of the thiol containing chemical compound of embodiment 4 is in the range from 0.1 to 20 wt % based on the total amount of the composition without solvent, more preferably it is 1 to 15 wt %, even more preferably it is 5 to 10 wt %.
5. The composition of any one of embodiments 1 to 4, further comprises a chemical compound comprising at least one group selected from the group consisting of straight-chain alkyl group having carbon atoms 1 to 80 or branched-chain alkyl group having carbon atoms 3 to 80, straight-chain aryl-alkyl group having carbon atoms 5 to 45, branched-chain aryl-alkyl group having carbon atoms 6 to 45, straight-chain cyclo-alkyl group having carbon atoms 4 to 45; and branched-chain cyclo-alkyl group having carbon atoms 6 to 45, where one or more non-adjacent CH₂ groups of the above mentioned groups is replaced by oxygen atom, C═O, C═S, C═Se, C═NH, SiH₂, SO, SO₂, OS, or CONH and where one or more H atoms may be replaced by D, F, Cl, Br, I, CN or NO₂; preferably the molecular weight of said chemical compound is 2000 or less, more preferably 1000 or less, even more preferably 500 or less and the molecular weight of said chemical compound is preferably 100 or more, more preferably 200 or more, even more preferably 300 or more, preferably said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid.
6. The composition of any one of embodiments 1 to 5, wherein said light emitting moiety comprises an outer layer containing a metal cation and a divalent anion; and
one or more types of organic moieties directly attached to the anion of the outer layer by covalent bond,
wherein said divalent anion of the outer layer is selected from Se²⁻, S²⁻, Te²⁻ O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺.
7. The composition of embodiment 6, wherein the organic moiety is represented by following chemical formula (I);

A-B—* (I)
wherein
A is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
B is a connecting unit, preferably B is **—(U)ₒ—(Y)ₘ—(CR^{IIa}R^{IIb})ₙ, wherein “*” represents the connecting point to “A”; and
“*” represents the connecting point to the anion in the outer layer.
8. The composition of embodiment 6 or 7, wherein the organic moiety is represented by following chemical formula (II), (III) or (III′);

L-(U)ₒ—(Y)ₘ—(CR^{IIa}R^{IIb})ₙ—* (II)
wherein
L is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
U is O, CH₂ or C═O;
Y is O, CH₂ or C═O;
R^{IIa} and R^{IIb} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIa} and R^{IIb} are hydrogen atom;
n is an integer 1 or more;
m is 0 or an integer 1 or more, preferably m is 1;
o is 0 or an integer 1 or more, preferably o is 1;
“*” represents the connecting point to the anion in the outer layer;

*—(CR^{IIIe}R^{IIIf})ₐ—(OCR^{IIIa}R^{IIIb}CR^{IIIc}R^{IIId})ₚ—(V)ᵣ—(CR^{IIIg}R^{IIIh})_{q}—Z (III)

*—(CR^{IIIg}R^{IIIh})_{q}—(V)ᵣ—(OCR^{IIIa}R^{IIIb}CR^{IIIc}R^{IIId})ₚ—Z (III′)
wherein
R^{IIIa}, R^{IIIb}, R^{IIIc}, R^{IIId}, R^{IIIe}, R^{IIIf}, R^{IIIg}, and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom; V is O, CH₂ or C═O;
Z is a hydrogen atom or an organic group, preferably Z is a hydrogen atom, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z is a hydrogen atom, a straight alkyl group having 1 to 25 carbon atoms, a branched alkyl group having 3 to 25 carbon atoms, more preferably it is a hydrogen atom, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1≤q≤5;
r is 0 or an integer 1;
“*” represents the connecting point to the anion in the outer layer.
9. The composition of any one of embodiments 6 to 8, wherein the organic moiety is represented by following chemical formula (IV):

*—(CR^{IIIe}R^{IIIf})ₐ—(OCR^{IIIa}R^{IIIb}CR^{IIIc}R^{IIId})p—(V)ᵣ—(CR^{IIIg}R^{IIIh})_{q}—Z′ (IV)
wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group,
a straight alkyl group having 1 to 10 carbon atoms, a branched alkyl group having 3 to 10 carbon atoms; preferably a hydrogen atom, a hydroxy group,
a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1;
V is O, CH₂ or C═O;
Z′ is a hydrogen atom a straight alkyl group having 1 to 25 carbon atoms, a branched alkyl group having 3 to 25 carbon atoms, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z′ is a straight alkyl group having 1 to 25 carbon atoms, a branched alkyl group having 3 to 25 carbon atoms or a hydrogen atom, more preferably it is a straight alkyl group having 1-15 carbon atoms, a branched alkyl group having 3-15 carbon atoms or a hydrogen atom, even more preferably it is a hydrogen atom;
r is 0 or an integer 1;
“*” represents the connecting point to the anion in the outer layer, preferably it is connected to S or Se atom in the outer layer.
10. The composition of any one of the preceding embodiments, wherein the organic moiety is covalently bound to the anion in the outer layer of an inorganic lattice, preferably it is not removed by a ligand exchange.
11. The composition of any one of the preceding embodiments, wherein metal cation is a transition metal of group 12 or group 14, preferably it is selected from one or more members of the group consisting of Zn²⁺, Hg²⁺ or Pb²⁺.
12. The composition of any one of the preceding embodiments, wherein said reactive monomer is a (meth)acrylate monomer selected from a mono-(meth)acrylate monomer, a di-(meth)acrylate monomer and/or a tri-(meth)acrylate monomer.

Preferably said two or more reactive monomers of the mixture is each independently selected from a mono-(meth)acrylate monomer, a di-(meth)acrylate monomer and/or a tri-(meth)acrylate monomer.
13. The composition of embodiment 12, said di-(meth)acrylate monomer is represented by following chemical formula (I^{b}), said mono-acrylate monomer is represented by following chemical formula (II^{b}) and/or said tri-(meth)acrylate monomer is represented by following chemical formula (III^{b});

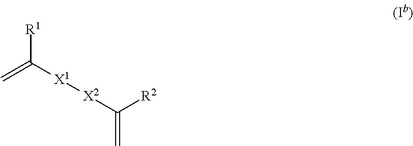

wherein
X¹ is an ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said alkyl group has carbon atoms 1 to 45, preferably said aryl group has carbon atoms 3 to 45;
preferably said ester group is represented by following formula (I^{bs1});

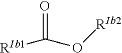

wherein R^{Ib1} is a single bond, a non-substituted or substituted alkylene chain having carbon atoms 1 to 5;
R^{Ib2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
X² is an ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said alkyl group has carbon atoms 1 to 45, preferably said aryl group has carbon atoms 3 to 45;
preferably said ester group is represented by following formula (I^{bs2});

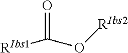

wherein R^{Ibs1} is a single bond, a non-substituted or substituted alkylene chain having carbon atoms 1 to 5;
R^{Ibs2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R¹ is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group; preferably said alkyl group has carbon atoms 1 to 45, preferably said aryl group has carbon atoms 3 to 45;
R² is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group; preferably said alkyl group has carbon atoms 1 to 45, preferably said aryl group has carbon atoms 3 to 45;

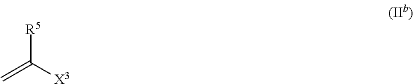

R⁵ is a hydrogen atom, halogen atom of Cl, Br, or F, methyl group, alkyl group, aryl group, alkoxy group, ester group, or a carboxylic acid group;
X³ is an ester group, alkyl group, cyclo-alkyl group, aryl group or an alkoxy group, in case of X³ is an ester group, said ester group is represented by following formula (II^{bs});

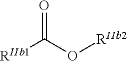

wherein R^{IIb1} is a single bond, a non-substituted or substituted alkylene chain having carbon atoms 1 to 5;
R^{IIb2} is a substituted or non-substituted alkyl group, cyclo group, cyclo-alkyl group, aryl group or an alkoxy group;
preferably the symbol X³ is

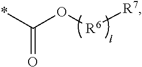

where “*” on the left side of the formula represents the connecting point to the end group C═CR⁵ of the formula (I);
I is 0 or 1;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

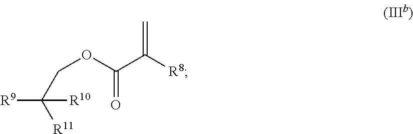

wherein R⁹ is hydrogen atom, a straight alkyl group having 1 to 25 carbon atoms or a (meth)acryl group represented by chemical formula (IV^{b})

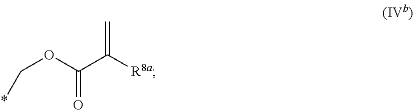

R¹⁰ is hydrogen atom, a straight alkyl group having 1 to 25 carbon atoms or a (meth)acryl group represented by chemical formula (V^{b})

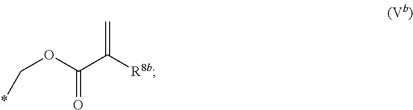

R¹¹ is hydrogen atom, a straight alkyl group having 1 to 25 carbon atoms or a (meth)acryl group represented by chemical formula (VI^{b})

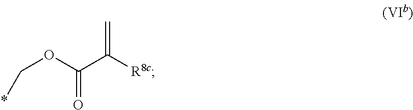

wherein R⁸, R^{8a}, R^{8b} and R^{8c} are, each independently or dependently of each other at each occurrence, H, CH₂CH₃ or CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹² to 1.0*10⁻¹⁵.
14. The composition of any one of preceding embodiments, wherein the total amount of the light emitting moiety is in the range from 0.1 wt. % to 90 wt. % based on the total amount of the composition, preferably from 10 wt. % to 70 wt. %, more preferably from 30 wt. % to 50 wt. %.
15. The composition of any one of preceding embodiments, comprises an another material selected from one or more members of the group consisting of;
another light emitting moiety which is different from the light emitting moiety of embodiment 1; scattering particles, anti-oxidants, radical quenchers, a photo initiators and surfactants.
16. The composition of any one of the preceding embodiments, wherein the composition comprises a solvent 10 wt % or less based on the total amount of the composition, more preferably it is 5 wt % or less, more preferably it is a solvent free composition, preferably said composition does not comprise any one of the following solvent selected from one or more members of the group consisting of ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; propylene glycol monoalkyl ethers, such as, propylene glycol monomethyl ether(PGME), propylene glycol monoethyl ether, and propylene glycol monopropyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, triethylene glycol and glycerin; esters, such as, ethyl 3-ethoxypropionate, methyl 3-methoxypropionate and ethyl lactate; and cyclic asters, such as, gamma-butyro-lactone; chlorinated hydrocarbons, such as chloroform, dichloromethane, chlorobenzene, trimethyl benzenes such as 1,3,5-trimethylbenzene, 1,2,4-trimethyl benzene, 1,2,3-trimethyl benzene, docecylbenzene, cyclohexylbenzene, 1,2,3,4-tetramethylbenzene, 1,2,3,5-tetramethylbenzene, 3-isopropylbiphenyl, 3-methylbiphenyl, 4-methylbiphenyl and dichlorobenzene, preferably said solvent is propylene glycol alkyl ether acetates, alkyl acetates, ethylene glycol monoalkyl ethers, propylene glycol, and propylene glycol monoalkyl ethers.
17. A process for preparing the composition of any one of preceding embodiments, comprising at least following steps,
(a) mixing a light emitting moiety, at least one reactive monomer or a mixture of two or more reactive monomers and a chemical compound represented by following chemical formula (X^{a}) to from a composition.

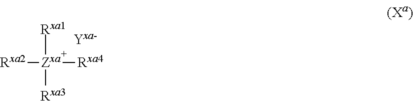

where symbols R^{xa1}, R^{xa1}, R^{xa1}, R^{xa1} Z^{xa}, Y^{xa-} are as defined in embodiment 1.

Optionally, a thiol containing chemical compound and/or a chemical compound as defined in any one of embodiments 4 to 6 is (are) added in step (a), preferably said thiol containing chemical compound is represented by chemical formula (P^{XA}) as defined in embodiment 4.
18. A composition obtainable or obtained from the process of embodiment 17.
19. Use of the composition of any one of embodiments 1 to 16, 18 in an electronic device, optical device, sensing device or in a biomedical device.
20. Method for forming a layer comprising:
S1) providing the composition of any one of embodiments 1 to 16 or 18 onto a substrate, preferably by ink-jetting;
S2) curing the composition or the formulation, preferably said curing is a photo curing performed by photo irradiation, thermal curing or a combination of a photo curing and a thermal curing.
21. A layer obtained or obtainable from the method of embodiment 20.
22. A layer containing at least;
Xi) a light emitting moiety, preferably it is a semiconducting light emitting nanoparticle;
Xii) a polymer made from at least one reactive monomer or a mixture of two or more reactive monomers, preferably said monomer having one or more of functional groups, more preferably it is a(meth)acrylate monomer;
Xiii) a chemical compound represented by following chemical formula (X^{a})

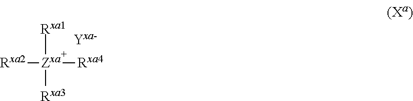

where symbols R^{xa1}, R^{xa1}, R^{xa1}, R^{xa1}, Z^{xa}, Y^{xa-} are as defined in embodiment 1 or 2.
23. A color conversion device (100) comprising at least a 1^{st} pixel (161) partly or fully filled with the layer of embodiment 21 or 22 comprising at least a matrix material (120) containing a light emitting moiety (110), and a bank (150) comprising at least a polymer material, preferably the color conversion device (100) further contains a supporting medium (170).
24. An optical device (300) containing at least one functional medium (320, 420, 520) configured to modulate a light or configured to emit light; and the layer of embodiment 21 or 22 or the color conversion device (100) of embodiment 23.
25. A light emitting moiety, preferably it is a semiconducting light emitting moiety as defined in the specification, comprising a 1^{st} ligand derived from the chemical compound represented by following chemical formula (X^{a}) as defined in the specification. Optionally, said light emitting moiety further contains a 2^{nd} ligand derived from the thiol containing chemical compound is represented by chemical formula (P^{XA}) as defined in the specification. Furthermore preferably, said light emitting moiety further contains a chemical compound comprising at least one group selected from the group consisting of straight-chain alkyl group having carbon atoms 1 to 80 or branched-chain alkyl group having carbon atoms 3 to 80, straight-chain aryl-alkyl group having carbon atoms 5 to 45, branched-chain aryl-alkyl group having carbon atoms 6 to 45, straight-chain cyclo-alkyl group having carbon atoms 4 to 45; and branched-chain cyclo-alkyl group having carbon atoms 6 to 45, where one or more non-adjacent CH₂ groups of the above mentioned groups is replaced by oxygen atom, C═O, C═S, C═Se, C═NH, SiH₂, SO, SO₂, OS, or CONH and where one or more H atoms may be replaced by D, F, Cl, Br, I, CN or NO₂; preferably the molecular weight of said chemical compound is 2000 or less, more preferably 1000 or less, even more preferably 500 or less and the molecular weight of said chemical compound is preferably 100 or more, more preferably 200 or more, even more preferably 300 or more, preferably said chemical compound further comprises at least one group selected from one or more of members of the group consisting of phosphine group, phosphine oxide group, phosphate group, phosphonate group, thiol group, tertiary amine, carboxyl group, hetero cyclic group, silane group, sulfonic acid, hydroxyl group, phosphonic acid as defined in the specification. Optionally, said light emitting moiety further comprises an outer layer containing a metal cation and a divalent anion; and
one or more types of organic moieties directly attached to the anion of the outer layer by covalent bond,
wherein said divalent anion of the outer layer is selected from Se²⁻, S²⁻, Te²⁻ O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺ as already defined in the specification. More details of the outer layer and the organic moiety is defined in the specification.

### Technical Effects

The present invention provides one or more of following effects, no color change of a composition containing light emitting moiety under air condition, improved thermal stability of an obtained layer (film), improved thermal stability of a light emitting moiety in a layer (film), improved dispersibility of a light emitting moiety in a composition, enabling a phase separation of light emitting moiety and matrix material after curing realizing an improved haze value of the cured film (cured composition), improved dispersibility of a light emitting moiety in an obtained layer, improved long term Quantum Yield (QY) stability of a light emitting moiety in the composition in a longer term storage with our without external light irradiation, improved long term External Quantum Efficiency (EQE) stability of a light emitting moiety in the composition in a longer term storage with our without external light irradiation, improved long term Quantum Yield (QY) stability of a light emitting moiety in the obtained layer (film) in a longer term storage with our without light external irradiation, improved long term External Quantum Efficiency (EQE) stability of a light emitting moiety in the obtained layer (film) in a longer term storage with our without external light irradiation, improved good compatibility of light emitting moiety with a matrix material in a composition and/or an obtained layer (film), and/or realizing easy handling of a composition containing a light emitting moiety and a matrix material, making composition suitable for inkjet printing.

The core and shell synthesis examples, reference examples and the working examples below provide descriptions of the present invention, as well as an in-detail description of their fabrication. However, the present invention is need not to be bound to the working examples.

### WORKING EXAMPLES

ODT=1-octadecanethiol
TBAB=Tetrabutylammonium bromide
LA=lauryl acrylate
HDDA=1,6-Hexanediol diacrylate
QD=quantum dot
PI=photo initiator
AO=antioxidant

### Working Example 1: Preparation of Red QD Ink 1

Red light emitting InP/ZnSe/ZnS QDs (PWL 628 nm) having mPEG thiol as a ligand dispersed in PGMEA are mixed with ODT and TBAB at 80 °C in reflux for about 90 min.

Then, the monomer mixture of LA and HDDA, and PI & AO are added as shown in table 1.

The formulation is shook for 10 minutes and volatiles are evaporated on rotary evaporator under vacuum at 25 °C. Remaining volatiles are removed under vacuum of 60 mTorr on a Schlenk line. Then, red QD ink 1 is obtained.

TABLE 1
Red QD ink 1

| | | |
|---|---|---|
| Red QDs | 40.00 | wt % |
| ODT | 6.00 | wt % |
| TBAB | 1.20 | wt % |
| LA | 30.78 | wt % |
| HDDA | 20.52 | wt % |
| PI (Omnirad ™819) | 0.50 | wt % |
| AO (Irganox ™1010) | 1.00 | wt % |
| Total | 100.00 | wt % |

### Comparative Example 1: Preparation of Comparative Red QD Ink 1

Comparative red QD ink 1 is fabricated in the same manner as described in working example 1 except for that the following materials as shown in table 2 are used instead of the materials used in working example 1.

TABLE 2
Comparative Red QD ink 1

| | | |
|---|---|---|
| Red QDs | 40.00 | wt % |
| ODT | 7.20 | wt % |
| TBAB | 0 | wt % |
| LA | 30.78 | wt % |
| HDDA | 20.52 | wt % |
| PI (Omnirad ™819) | 0.50 | wt % |
| AO (Irganox ™1010) | 1.00 | wt % |
| Total | 100.00 | wt % |

### Working Examples 2-4: Preparation of Red QD Inks 2 to 4

Red QD inks 2 to 4 (corresponding to working examples 2 to 4) are obtained in the same manner as described in working example 4 except for that the ODT and TBAB are added in a different ratio as shown in table 3.

TABLE 3

| | QD ink 2 | | QD ink 3 | | QD ink 4 | |
|---|---|---|---|---|---|---|
| Red QDs | 40.00 | wt % | 40.00 | wt % | 40.00 | wt % |
| ODT | 6.4 | wt % | 6.8 | wt % | 7.12 | wt % |
| TBAB | 0.80 | wt % | 0.40 | wt % | 0.08 | wt % |
| LA | 30.78 | wt % | 30.78 | wt % | 30.78 | wt % |
| HDDA | 20.52 | wt % | 20.52 | wt % | 20.52 | wt % |
| PI (Omnirad ™819) | 0.50 | wt % | 0.50 | wt % | 0.50 | wt % |
| AO (Irganox ™1010) | 1.00 | wt % | 1.00 | wt % | 1.00 | wt % |
| Total | 100.00 | wt % | 100.00 | wt % | 100.00 | wt % |

### Working Example 5: Film Formation

Films are formed by filling glass sandwiches cells (gap around 10 μm) with QD inks described in the previous examples. The films are cured by UV light (300 mW/cm² for 10 seconds). The cells are then opened, resulting in an open films deposited in one of the cell glass.

The open films are heated (thermal annealing) at 180 °C for 30 minutes under inert atmosphere. After the thermal annealing, the films are stored in a humidity controlled chamber under 25 °C and relative humidity (RH) of 45%.

### Working Example 6: EQE Measurement, BL Calculation and PWL, FWHM Measurements

The EQE value is measured 1 h after the thermal annealing, as indicated in the table 4 below.
EQE=Photons [Emission light]/Photons [Excitation light measured without sample in place];

According to the present invention, said EQE is measured by the following EQE measurement process at room temperature which is based on using an integrating sphere, equipped with a 450 nm excitation light source coupled in via an optical fiber, and a spectrometer (Compass X, BWTEK), and which consists of a first measurement using air as the reference to detect the incident photons of the excitation light and a second measurement with the sample or test cell placed in front of the integrating sphere in between the opening of the integrating sphere and the exit of the optical fiber to detect the photons incident from the excitation light source transmitted through the sample and the photos emitted from the sample or test cell, whereas for both cases photons exiting the integrating sphere are counted by the spectrometer and EQE and BL calculation is done with the following equations and the number of photons of the excitation light and emission light is calculated by integration over the following wavelength ranges;
EQE=Photons [Emission light]/Photons [Excitation light measured without sample in place];
BL=Photons [−Excitation light measured with sample in place]/Photons [Excitation light measured without sample in place];

Emission light if red light emitting moieties are used: 580 nm-780 nm

Excitation light: 390 nm-490 nm. At the same time, PWL and FWHM values of the test cells are also measured. Table 4 shows the results.

TABLE 4

| | Comparative | QD ink 1 | QD ink 2 | QD ink 3 | QD ink 4 |
|---|---|---|---|---|---|
| EQE | 36.4% | 36.0% | 36.2% | 36.3% | 36.4% |
| BL | 8.3% | 11.2% | 10.3% | 10.1% | 9.3% |
| PWL | 638.3 nm | 638.3 nm | 638.3 nm | 638.3 nm | 638.6 nm |
| FWHM | 35.6 nm | 35.5 nm | 35.5 nm | 35.5 nm | 35.4 nm |

### Working Example 7: Observation of Color Change of the QD Inks Under Air

The obtained QD inks 1 to 4 and Comparative QD ink 1 are each separately dropped onto different glass plates. Color change of the dropped QD inks under air condition at room temperature at 0 min, 5 min, and 20 min are checked by human eyes. Table 5 shows the results.

TABLE 5

| | Comparative | QD ink 1 | QD ink 2 | QD ink 3 | QD ink 4 |
|---|---|---|---|---|---|
| Color | NG | OK | OK | OK | OK |
| change | | | | | |

In the table, “N G” means color change of the dropped D ink is observed under Air condition and “OK” means no color change of the dropped QD ink is observed.

### Results

The red QD inks of working example 1 to 4 shows no color change while comparative red QD ink from comparative example 1 shows a significant color change from red color to light pink color. Thus, the color change is solved by adding TBAB.

### Working Example 8: Preparation of Red QD Ink 5

Red QD ink 5 is fabricated in the same manner as described in working example 3 (red QD ink 3) except for that two types of red light emitting InP/ZnSe/ZnS QDs having mPEG thiol as a ligand dispersed in PGMEA are used (Red QD with PWL617 nm: red QD with PWL629 nm, mixing ratio 4:6) instead of the red QD used in working example 3.

TABLE 6
Red QD ink composition 1

| | | |
|---|---|---|
| Red QDs | 40.00 | wt % |
| (PWL617nm):Red | | |
| QDs (PWL629nm) | | |
| 4:6 ratio | | |
| ODT | 6.80 | wt % |
| TBAB | 0.40 | wt % |
| LA | 30.78 | wt % |
| HDDA | 20.52 | wt % |
| PI (Omnirad ™819) | 0.50 | wt % |
| AO (Irganox ™1010) | 1.00 | wt % |
| Total | 100.00 | wt % |

Table 7 shows the results of the measurements performed in the same manner as described in working examples 5 to 7.

QD ink 5

| | |
|---|---|
| EQE | 34.8% |
| BL | 9.4% |
| PWL | 636.9 nm |
| FWHM | 40.0 nm |
| Color change | OK |

1.-17. (canceled)

18. A composition comprising at least;
i) a light emitting moiety,
ii) at least one reactive monomer or a mixture of two or more reactive monomers; and
iii) a chemical compound represented by following chemical formula (X^{a}). 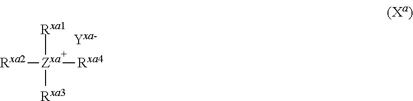
wherein
R^{xa1}, R^{xa1}, R^{xa1}, R^{xa1} are each independently of each other, selected from straight chain alkyl group having 1-25 carbon atoms; each of which may be substituted by one or more groups R^{a},
R^{a} is at each occurrence, identically or differently, H, D, a straight chain alkyl or alkoxy group having 1 to 40 carbon atoms; a branched or cyclic alkyl or alkoxy group having 3 to 40 carbon atoms; a straight-chain alkenyl or alkynyl group having 2 to 40 carbon atoms; a branched alkenyl group or alkynyl group having 3 to 40 carbon atoms; an aromatic or heteroaromatic ring system having 5 to 40 aromatic ring atoms, wherein in each of the above-mentioned groups one or more H atoms may be replaced by D, F, Cl, Br, I, and where two or more adjacent substituents R^{a} here may optionally form a mono- or polycyclic, aliphatic ring system with one another;
Z^{xa} is N, P or As;
Y^{xa-} is a halogen containing monovalent anion.

19. The composition of claim 18, wherein R^{xa1}, R^{xa1}, R^{xa1}, R^{xa1} of the chemical formula (X^{a}) are each independently of each other, selected from straight chain alkyl group having 1-25 carbon atoms; a branched or cyclic alkyl group having 3-25 carbon atoms; a straight-chain alkenyl or alkynyl group having 2 to 25 carbon atoms; a branched alkenyl group or alkynyl group having 3 to 25 carbon atoms; each of which may be substituted by one or more groups R^{a};
Z^{xa} is N, P or As;
Y^{xa-} is a halogen containing monovalent anion.

20. The composition of claim 18, wherein the total amount of the chemical compound of chemical formula (X^{a}) is in the range from 0.001 to 2.0 wt % based on the total amount of the composition without solvent.

21. The composition of claim 18, further comprises a thiol containing chemical compound.

22. The composition of claim 18, further comprises a chemical compound comprising at least one group selected from the group consisting of straight-chain alkyl group having carbon atoms 1 to 80 or branched-chain alkyl group having carbon atoms 3 to 80, straight-chain aryl-alkyl group having carbon atoms 5 to 45, branched-chain aryl-alkyl group having carbon atoms 6 to 45, straight-chain cyclo-alkyl group having carbon atoms 4 to 45; and branched-chain cyclo-alkyl group having carbon atoms 6 to 45, where one or more non-adjacent CH₂ groups of the above mentioned groups is replaced by oxygen atom, C═O, C═S, C═Se, C═NH, SiH₂, SO, SO₂, OS, or CONH and where one or more H atoms may be replaced by D, F, Cl, Br, I, CN or NO₂.

23. The composition of claim 18, wherein said light emitting moiety comprises an outer layer containing a metal cation and a divalent anion; and
one or more types of organic moieties directly attached to the anion of the outer layer by covalent bond,
wherein said divalent anion of the outer layer is selected from Se²⁻, S²⁻, Te²⁻ O²⁻ or a combination thereof.

24. The composition of claim 23, wherein the organic moiety is represented by following chemical formula (I);
A-B—* (I)
wherein
A is an organic group;
B is a connecting unit; and
“*” represents the connecting point to the anion in the outer layer.

25. The composition of claim 18, wherein said reactive monomer is a (meth)acrylate monomer selected from a mono-(meth)acrylate monomer, a di-(meth)acrylate monomer and/or a tri-(meth)acrylate monomer.

26. The composition of claim 25, said di-(meth)acrylate monomer is represented by following chemical formula (I^{b}), said mono-acrylate monomer is represented by following chemical formula (II^{b}) and/or said tri-(meth)acrylate monomer is represented by following chemical formula (III^{b}); 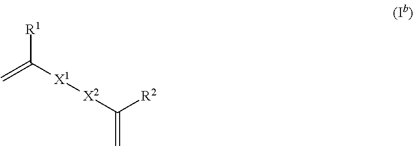
wherein
X¹ is an ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R^{Ib2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
X² is an ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R^{Ibs2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R¹ is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group;
R² is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group;
R⁵ is a hydrogen atom, halogen atom of Cl, Br, or F, methyl group, alkyl group, aryl group, alkoxy group, ester group, or a carboxylic acid group;
X³ is an ester group, alkyl group, cyclo-alkyl group, aryl group or an alkoxy group, in case of X³ is an ester group, said ester group is represented by following formula (II^{bs}); 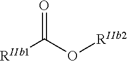
wherein R^{IIb1} is a single bond, a non-substituted or substituted alkylene chain having carbon atoms 1 to 5;
R^{IIb2} is a substituted or non-substituted alkyl group, cyclo group, cyclo-alkyl group, aryl group or an alkoxy group;
1 is 0 or 1;
R⁶ is a straight alkylene chain or alkoxylene chain having 1 to 25 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, which may be substituted by one or more radicals R^{a}, where one or more non-adjacent CH₂ groups may be replaced by R^{a}C═CR^{a}, C≡C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another; 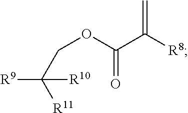
wherein R⁹ is hydrogen atom, a straight alkyl group having 1 to 25 carbon atoms or a (meth)acryl group represented by chemical formula (IV^{b}) 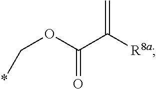
R¹⁰ is hydrogen atom, a straight alkyl group having 1 to 25 carbon atoms or a (meth)acryl group represented by chemical formula (V^{b}) 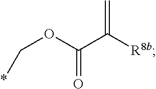
R¹¹ is hydrogen atom, a straight alkyl group having 1 to 25 carbon atoms or a (meth)acryl group represented by chemical formula (VI^{b}) 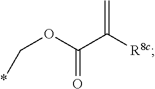
wherein R⁸, R^{8a}, R^{8b} and R^{8c} are, each independently or dependently of each other at each occurrence, H, CH₂CH₃ or CH₃;
wherein at least one of R⁹, R¹⁰ and R¹¹ is a (meth)acryl group.

27. The composition of claim 18, comprises an another material selected from one or more members of the group consisting of,
another light emitting moiety which is different from the light emitting moiety of claim 18;
scattering particles, anti-oxidants, radical quenchers, a photo initiators and surfactants.

28. A process for preparing the composition of claim 18, comprising at least following steps,
(a) mixing a light emitting moiety, at least one reactive monomer or a mixture of two or more reactive monomers and a chemical compound represented by following chemical formula (X^{a}) to from a composition. 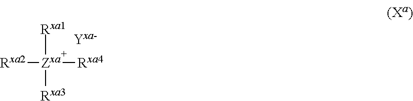
where symbols R^{xa1}, R^{xa1}, R^{xa1}, R^{xa1} Z^{xa}, Y^{xa-} are as defined in claim 18.

29. A composition obtained from the process of claim 28.

30. A method for forming a layer comprising:
S1) providing the composition of claim 18 onto a substrate;
S2) curing the composition or the formulation.

31. A layer obtained from the method of claim 30.

32. A layer containing at least;
Xi) a light emitting moiety;
Xii) a polymer made from at least one reactive monomer or a mixture of two or more reactive monomers;
Xiii) a chemical compound represented by following chemical formula (X^{a}) 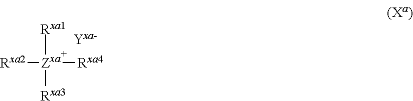
where symbols R^{xa1}, R^{xa1}, R^{xa1}, R^{xa1} Z^{xa}, Y^{xa-} are as defined in claim 18.

33. A color conversion device comprising at least a 1^{st} pixel partly or fully filled with the layer of claim 31 comprising at least a matrix material containing a light emitting moiety, and a bank comprising at least a polymer material.

34. An optical device containing at least one functional medium configured to modulate a light or configured to emit light; and the layer of claim 31.
